(19) United States
(12) Patent Application Publication
(10) Pub. No.: US 2026/0020409 A1
(43) Pub. Date: Jan. 15, 2026

(54) DISPLAY APPARATUS

(71) Applicant: LG Display Co., Ltd., Seoul (KR)

(72) Inventors: HyeSun JUNG, Seoul (KR); TaeYoon KIM, Seoul (KR); BungGoo KIM, Paju-si (KR); HyoungHo AHN, Paju-si (KR); HeeWon LEE, Paju-si (KR); JunYoung JO, Paju-si (KR)

(73) Assignee: LG Display Co., Ltd., Seoul (KR)

(21) Appl. No.: 19/221,051

(22) Filed: May 28, 2025

(30) Foreign Application Priority Data
Jul. 10, 2024 (KR) 10-2024-0090977

(51) Int. Cl. H10H 29/49; H01L 25/16; H10H 29/37; H10H 29/85

(52) U.S. Cl. CPC H10H 29/49; H10H 29/37; H10H 29/8508; H01L 25/167

(57) ABSTRACT

A display apparatus is provided. The display apparatus comprises a substrate, one or more pixel driving circuits disposed on the substrate, a plurality of insulating layer disposed on the pixel driving circuit, a plurality of banks disposed on the plurality of insulating layers. A plurality of micro LEDs is disposed on the banks and electrically connected to the pixel driving circuit through a plurality of first electrodes, which are positioned between the banks and the micro LEDs. A plurality of signal lines is disposed below the banks so as to overlap the banks and directly contact the first electrodes. This configuration enables efficient signal transmission and improves pixel integration by reducing the interval between adjacent pixels. Additionally, by overlapping the banks with signal lines and avoiding routing between adjacent banks, electrical connection between signal lines carrying different signals is suppressed, thereby minimizing interference and improving circuit reliability.

### CROSS-REFERENCE TO RELATED APPLICATIONS

This application claims the priority of Korean Patent Application No. 10-2024-0090977 filed on Jul. 10, 2024, in the Korean Intellectual Property Office, the disclosure of which is incorporated herein by reference.

### BACKGROUND

### Technical Field

The present disclosure relates to a display apparatus.

### Description of the Related Art

A display apparatus is applied to various electronic apparatuses such as TV, mobile phones, laptops, and tablets.

The display apparatus includes an organic light emitting display (OLED) apparatus that emits light by itself, a liquid crystal display (LCD) apparatus that requires a separate light source, etc.

Recently, the display apparatus including a light emitting diode (LED) is attracting attention as a next-generation display apparatus. Since the light emitting diode is made of an inorganic material rather than an organic material, the light emitting diode may have a fast-lighting speed and excellent light emitting efficiency, and may display a high brightness image, compared to the liquid crystal display apparatus or the organic light emitting display apparatus.

### BRIEF SUMMARY

The display apparatus features a signal routing and pixel layout structure that improves pixel density, reduces power consumption, and increases manufacturing yield. Signal lines are placed below and overlapping the micro LED banks, allowing for narrower spacing between pixels while maintaining sufficient line width to reduce voltage drop. This arrangement also reduces the need to place signal lines between adjacent banks, thereby reducing electrical interference and enabling a more compact pixel layout. Each pixel includes two micro LEDs of the same color-one primary and one redundant-allowing selection of a functional LED after transfer to address any placement or performance issues.

The apparatus uses a multi-layered structure to route driving signals through stacked organic insulating layers, which improves signal separation and routing efficiency. The flexible substrate design includes patterned link lines and selectively removed insulating layers in the bending area to reduce mechanical stress and enhance durability in foldable regions. A transparent common electrode with multiple contact points allows light to emit from the top side while simplifying electrical connections. These features enable a high-resolution, energy-efficient, and mechanically reliable display panel.

For example, various embodiments of the present disclosure provide a display apparatus which improves a pixel integration degree by narrowing an interval between adjacent pixels.

Various embodiments of the present disclosure provide a display apparatus which suppresses a problem in that signal lines which transmit different signals, among adjacent signal lines, are electrically connected.

Various embodiments of the present disclosure provide a display apparatus in which a problem of an increased resistance of a signal line is suppressed to reduce power consumption and improve a lifespan.

Technical benefits of the present disclosure are not limited to the above-mentioned benefits, and other benefits, which are not mentioned above, can be clearly understood by those skilled in the art from the following descriptions.

A display apparatus according to an exemplary embodiment of the present disclosure comprises a substrate, one or more pixel driving circuits disposed on the substrate, a plurality of insulating layer disposed on the pixel driving circuit, a plurality of banks disposed on the plurality of insulating layers, a plurality of micro LEDs which is disposed on the plurality of banks and is electrically connected to the pixel driving circuit, a plurality of first electrodes which is disposed between the plurality of banks and the plurality of micro LEDs and a plurality of signal lines which is in direct contact with the plurality of first electrodes and is disposed below the plurality of banks so as to overlap the plurality of banks.

A display apparatus according to another exemplary embodiment of the present disclosure comprise a substrate including an active area including a plurality of sub pixels and a non-active area, one or more pixel driving circuits disposed on the substrate, a plurality of insulating layers disposed on the substrate, a plurality of banks disposed in the plurality of sub pixels on the plurality of insulating layers, a plurality of micro LEDs disposed on the plurality of banks, a plurality of first electrodes which is disposed between the plurality of banks and the plurality of micro LEDs and a plurality of signal lines which electrically connects the plurality of first electrodes and the pixel driving circuit, wherein the plurality of signal lines overlaps the plurality of banks and the plurality of signal lines is conductive layers which are disposed to be adjacent to the bank, among conductive layers disposed below the bank.

According to the present disclosure, a line width of a plurality of signal lines is ensured to suppress a voltage drop problem.

According to the present disclosure, an interval between the plurality of banks is reduced to provide a display apparatus with a high resolution.

According to the present disclosure, a resistance of the plurality of signal lines is reduced to provide a low-power display apparatus.

The effects according to the present disclosure are not limited to the contents exemplified above, and more various effects are included in the present disclosure.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is an exploded perspective view of a display apparatus according to an exemplary embodiment of the present disclosure;

FIG. 2 is a plan view of a display apparatus according to an exemplary embodiment of the present disclosure;

FIG. 3 is an enlarged view of a display apparatus according to an exemplary embodiment of the present disclosure;

FIG. 4 is a view illustrating a circuit structure according to an exemplary embodiment of the present disclosure;

FIG. 5 is a plan view of a display apparatus according to an exemplary embodiment of the present disclosure;

FIG. 6 is a plan view of a display apparatus according to an exemplary embodiment of the present disclosure;

FIG. 7 is a plan view of a display apparatus according to an exemplary embodiment of the present disclosure;

FIG. 8 is a cross-sectional view taken along VIII-VIII′ of FIG. 3;

FIG. 9 is an enlarged perspective view of a display apparatus according to an exemplary embodiment of the present disclosure;

FIG. 10 is a cross-sectional view of a display apparatus according to an exemplary embodiment of the present disclosure; and

FIGS. 11 to 14 are views illustrating devices to which a display apparatus according to exemplary embodiments of the present disclosure is applied.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When the relation of a time sequential order is described using the terms such as “after,” “continuously to,” “next to,” and “before,” the order may not be continuous unless the terms are used with the term “immediately” or “directly.”

Although the terms first, second, or the like are used to describe various components, these components are not limited by these terms. These terms are only used to distinguish one component from another. Thus, a first component referred to below may also be a second component within the technical scope of the present disclosure.

In describing components of the present disclosure, terms such as first, second, A, B, (a), or (b) may be used. These terms are only intended to distinguish the component from other components, and the nature, order, sequence, or number of the components are not limited by the terms.

When a component is described as being “connected,” “coupled,” “joined,” or “attached” to another component, it should be understood that that the component can be directly connected, coupled, joined, or attached to that other component, but that other components may also be interposed between the components which can be indirectly connected, coupled, joined, or attached, unless otherwise expressly stated.

When a component or layer is described as “contacting” or “overlapping” another component or layer, it should be understood that the component or layer may directly contact or overlap the other component or layer, but that other components may also be interposed between the components that may indirectly contact or overlap each other, unless specifically stated otherwise.

To further elaborate, as used herein, the term “connected” is intended to have the broadest possible meaning. Specifically, the phrase “A is connected to B” encompasses both a direct connection—where no intervening components or elements are present-and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

“At least one” should be understood to include any combination of one or more of the associated components. For example, “at least one of the first, second, and third components” could be understood to include any combination of two or more of the first, second, and third components, as well as the first, second, or third components.

A “first direction”, “second direction”, “third direction”, “X-axis direction”, “Y-axis direction” and “Z-axis direction” should not be interpreted as merely geometric relationships in which the relationship between them is perpendicular to each other, but may mean a broader directionality within the scope in which the configuration of the present disclosure can function functionally.

The features of various embodiments of the present disclosure can be partially or entirely adhered to or combined with each other and can be interlocked and operated in technically various ways, and the embodiments can be carried out independently of or in association with each other.

Hereinafter, a display apparatus according to exemplary embodiments of the present disclosure will be described in detail with reference to accompanying drawings.

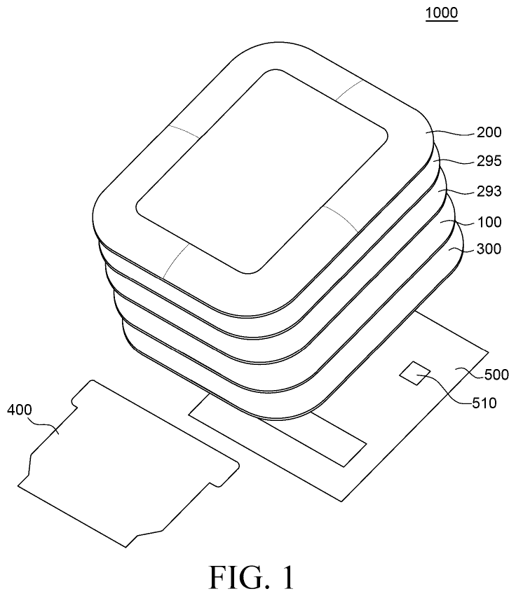

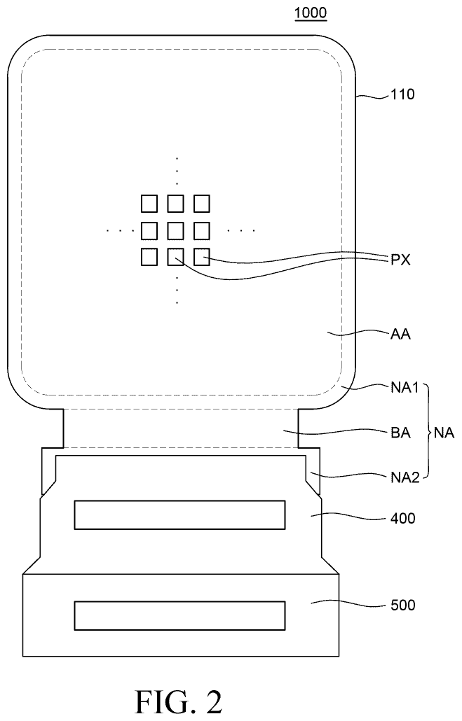

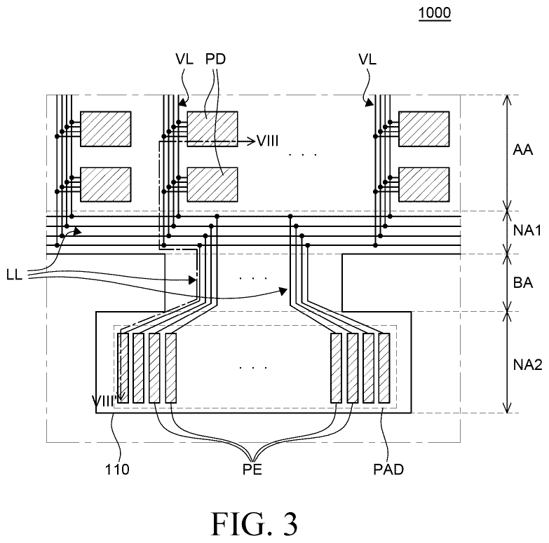

FIG. 1 is a perspective view illustrating a display apparatus according to an exemplary embodiment of the present disclosure, FIG. 2 is a plan view of a display apparatus according to an exemplary embodiment of the present disclosure, and FIG. 3 is an enlarged view of a display apparatus according to an exemplary embodiment of the present disclosure.

Referring to FIGS. 1 to 3, a display apparatus 1000 according to an exemplary embodiment of the present disclosure may include a display panel 100, a polarization layer 293, an adhesive layer 295, a cover member 200, a support substrate 300, a flexible circuit board 400, and a printed circuit board 500.

For example, the display apparatus 1000 may include a substrate 110. The substrate 110 may be a member which supports other components of the display apparatus 1000. The substrate 110 may be formed of an insulating material. For example, the substrate 110 may be formed of glass or resin. Further, the substrate 110 may also be formed of a material having a flexibility. For example, the substrate 110 may be formed of a plastic material having flexibility, such as polyimide (PI), but the exemplary embodiments of the present disclosure are not limited thereto.

The display panel 100 may implement information, videos, and/or images which are provided to users. For example, the display panel 100 may include an active area AA and a non-active area NA. For example, the substrate 110 may include an active area AA and a non-active area NA. However, the active area AA and the non-active area NA are not mentioned to be limited to the substrate 110, but may be mentioned for the entire display apparatus 1000.

The active area AA may be an area where images are displayed. The active area AA may include a plurality of pixels PX. Each of the plurality of pixels PX may be configured by a plurality of sub pixels. A plurality of micro LEDs may be disposed in each of the plurality of sub pixels. The plurality of micro LEDs may be configured in different manners depending on the type of the display apparatus 1000.

The non-active area NA may be an area where no image is displayed. In the non-active area NA, various wiring lines and circuits for driving the plurality of pixels PX of the active area AA may be disposed. For example, in the non-active area NA, various wiring lines and driving circuits may be mounted and a pad unit PAD to which an integrated circuit and a printed circuit are connected may be disposed, but the exemplary embodiments of the present disclosure are not limited thereto.

For example, the driving circuit may be a data driving circuit and/or a gate driving circuit, but the exemplary embodiments of the present disclosure are not limited thereto. Wiring lines through which a control signal for controlling driving circuits is supplied may be disposed. For example, the control signal may include various timing signals including a clock signal, an input data enable signal, and synchronization signals, but the exemplary embodiments of the present disclosure are not limited thereto. The control signal may be received through the pad unit PAD. For example, in the non-active area NA, link lines LL may be disposed to transmit signals. For example, driving components, such as the flexible circuit board 400 and the printed circuit board 500, may be connected to the pad unit PAD.

According to the present disclosure, the non-active area NA may include a first non-active area NA1, a bending area BA, and a second non-active area NA2. For example, the first non-active area NA1 may be an area which encloses at least a part of the active area AA. The bending area BA is an area extending from at least one side, among a plurality of sides of the first non-active area NA1 and may be a bendable area. The second non-active area NA2 is an area extending from the bending area BA and the pad unit PAD may be disposed therein. For example, the bending area BA may be in a bent state and the other areas of the substrate 110 excluding the bending area BA may be in a flat state. In this case, as the bending area BA is bent, the second non-active area NA2 may be located on a rear surface of the active area AA, However, the exemplary embodiments of the present disclosure are not limited thereto.

The active area AA of the substrate 110 or the display apparatus 1000 may be configured with various shapes depending on a design of the display apparatus 1000. For example, the active area AA may be configured with a rectangular shape formed with four rounded corners, but the exemplary embodiments of the present disclosure are not limited thereto. As another example, the active area AA may be configured with a rectangular shape formed with four right-angled corners or a circular shape, but the exemplary embodiments of the present disclosure are not limited thereto.

According to the present disclosure, a width of the second non-active area NA2 in which the plurality of pad electrodes PE is disposed may be larger than a width of the bending area BA in which only a plurality of link lines LL is disposed. Further, a width of the active area AA in which the plurality of sub pixels is disposed may be larger than a width of the bending area BA in which only a plurality of link lines LL is disposed. Even though in the drawing, it is illustrated that the width of the bending area BA is smaller than a width of the other area of the substrate 110, the shape of the substrate 110 including the bending area BA is illustrative and the exemplary embodiments of the present disclosure are not limited thereto.

Referring to FIG. 3, a plurality of pixel driving circuits PD may be disposed in the active area AA. The plurality of pixel driving circuits PD may be circuits for driving micro LEDs of the plurality of sub pixels. Each of the plurality of pixel driving circuits PD includes a plurality of transistors including a driving transistor and a storage capacitor and supplies a control signal, a power, and a driving current to the micro LEDs of the plurality of sub pixels to control an emission operation of the plurality of micro LEDs. For example, the pixel driving circuit PD may include a power line and a signal line for controlling emission on/off of the micro LED and/or an emission time. For example, the plurality of pixel driving circuits PD may be driving drives manufactured using a metal-oxide-silicon field effect transistor (MOSFET) manufacturing process on a semiconductor substrate, but the exemplary embodiments of the present disclosure are not limited thereto. The driving driver includes a plurality of pixel driving circuits PD and may drive a plurality of sub pixels.

Referring to FIG. 1 together, the flexible circuit board 400 and the printed circuit board 500 may be disposed below the display panel 100. The flexible circuit board 400 and the printed circuit board 500 may be disposed at least at one edge of the display panel 100, but the exemplary embodiments of the present disclosure are not limited thereto. One side of the flexible circuit board 400 may be attached to the display panel 100 and the other side may be attached to the printed circuit board 500, but the exemplary embodiments of the present disclosure are not limited thereto. The flexible circuit board 400 may be a flexible film, but the exemplary embodiments of the present disclosure are not limited thereto.

A pad unit PAD including a plurality of pad electrodes PE may be disposed in the second non-active area NA2. In the pad unit PAD, a driving component including one or more flexible circuit board (or a flexible film) 400 and the printed circuit board 500 may be attached or bonded. The plurality of pad electrodes PE of the pad unit PAD is electrically connected to one or more flexible circuit boards (or flexible films) 400 and may transmit various signals (or powers) from the printed circuit board 500 and the flexible circuit board (or a flexible film) 400 to the plurality of pixel driving circuits PD of the active area AA.

The flexible circuit board (or flexible film) 400 may be a film on which various components are disposed on a base film having ductility. For example, driving ICs such as a gate driver IC or a data driver IC may be disposed in the flexible circuit board (or flexible film) 400, but the exemplary embodiments of the present disclosure are not limited thereto. The driving IC may be a component which processes data and driving signals to display images. The driving IC may be disposed by a chip on glass (COG), a chip on film (COF), or a tape carrier package (TCP) technique depending on a mounting method, but the exemplary embodiments of the present disclosure are not limited thereto. The flexible circuit board (or flexible film) 400 may be attached or bonded onto the plurality of pad electrodes PE through a conductive adhesive layer, but the exemplary embodiments of the present disclosure are not limited thereto.

The printed circuit board 500 may be a component which is electrically connected to one or more flexible circuit boards (or flexible films) 400 and supplies a signal to the driving IC. The printed circuit board 500 is disposed at one side of the flexible circuit board (or flexible film) 400 to be electrically connected to the flexible circuit board (or flexible film) 400. On the printed circuit board 500, various components for supplying various signals to the driving IC may be disposed. For example, on the printed circuit board 500, various components, such as a timing controller, a power source, a memory, or a processor, may be disposed. For example, the printed circuit board 500 may include a power management integrated circuit (PMIC), but the exemplary embodiments of the present disclosure are not limited thereto.

The printed circuit board 500 may include at least one hole 510, but the exemplary embodiments of the present disclosure are not limited thereto. An internal component which senses ambient light or temperature to be supplied to a plurality of sensors may be disposed in an area corresponding to at least one hole 510. For example, the internal component may include an ambient light sensor (ALS) or a temperature sensor, but the exemplary embodiments of the present disclosure are not limited thereto. For example, the hole 510 may be a transmission hole, but the exemplary embodiments of the present disclosure are not limited thereto.

Referring to FIG. 1, a polarization layer 293 may be disposed on the display panel 100. The polarization layer 293 may suppress or reduce the influence on the micro LED caused by light generated from an external light source and entering the display panel 100.

A cover member 200 may be disposed on the polarization layer 293. The cover member 200 may be a member for protecting the display panel 100. The adhesive layer 295 may be disposed between the polarization layer 293 and the cover member 200. The cover member 200 may be attached to the display panel 100 using the adhesive layer 295. The adhesive layer 295 may include an optically clear adhesive (OCA), an optically clear resin (OCR), or a pressure sensitive adhesive (PSA), but the exemplary embodiments of the present disclosure are not limited thereto.

The support substrate 300 may be disposed between the display panel 100 and the printed circuit board 500. The support substrate 300 may reinforce a rigidity of the display panel 100. The support substrate 300 may be a back plate, but the exemplary embodiments of the present disclosure are not limited thereto.

Referring to FIGS. 1 to 3, the plurality of link lines LL may be disposed in the non-active area NA. The plurality of link lines LL may be wiring lines which transmit various signals from one or more flexible circuit boards (or flexible films) 400 and the printed circuit board 500 to the active area AA. The plurality of link lines LL extends from the plurality of pad electrodes PE of the second non-active area NA2 toward the bending area BA and the first non-active area NA1 to be electrically connected to the plurality of driving lines VL of the active area AA. The plurality of pixel driving circuits PD is supplied with signals from one or more flexible circuit boards (or flexible films) 400 and the printed circuit board 500 through the driving line VL of the active area AA and the link line LL of the non-active area NA to be driven.

For example, the plurality of driving lines VL may be wiring lines for transmitting a signal output from the flexible circuit board (or flexible film) 400 and the printed circuit board 500 to the plurality of pixel driving circuits PD together with the plurality of link lines LL. The plurality of driving lines VL is disposed in the active area AA to be electrically connected to each of the plurality of pixel driving circuits PD. The plurality of driving lines VL extends toward the non-active area NA from the active area AA to be electrically connected to the plurality of link lines LL. Accordingly, a signal output from the flexible circuit board (or flexible film) 400 and the printed circuit board 500 may be transmitted to each of the plurality of pixel driving circuits PD through the plurality of link lines LL and the plurality of driving lines VL.

As the bending area BA is bent, a part of the plurality of link lines LL may be bent together. A stress is concentrated in the bent part of the link line LL, which may cause a crack on the link line LL. Accordingly, the plurality of link lines LL may be configured by a conductive material having excellent ductility to reduce the crack caused when the bending area BA is bent. For example, the plurality of link lines LL may be configured by a conductive material having excellent ductility, such as gold (Au), silver (Ag), or aluminum (Al), but the exemplary embodiments of the present disclosure are not limited thereto. Further, the plurality of link lines LL may be configured by one of various conductive materials used for the active area AA. For example, the plurality of link lines LL may be configured by molybdenum (Mo), chrome (Cr), titanium (Ti), nickel (Ni), neodymium (Nd), copper (Cu), and an alloy of silver (Ag) and magnesium (Mg) or an alloy thereof, but the exemplary embodiments of the present disclosure are not limited thereto. The plurality of link lines LL may be configured by a multi-layered structure including various conductive materials. For example, the plurality of link lines LL may be configured with a triple layered structure of titanium (Ti)/aluminum (Al)/titanium (Ti), but the exemplary embodiments of the present disclosure are not limited thereto.

The plurality of link lines LL may be configured with various shapes to reduce a stress. At least a part of the plurality of link lines LL disposed on the bending area BA may extend in the same direction as an extending direction of the bending area BA or extend in a different direction from the extending direction of the bending area BA to reduce a stress. For example, when the bending area BA extends in one direction toward the second non-active area NA2 from the first non-active area NA1, at least a part of the link line LL disposed on the bending area BA may extend in an inclined direction from one direction. As another example, at least a part of the plurality of link lines LL may be configured by various shapes of patterns. For example, at least a part of the plurality of link lines LL disposed on the bending area BA may have a shape in which a conductive pattern having at least one shape of a diamond shape, a rhombus shape, a trapezoidal wave shape, a triangular wave shape, a sawtooth wave shape, a sine wave shape, a circular shape, an omega (Ω) shape may be repeatedly disposed. However, the exemplary embodiments of the present disclosure are not limited thereto. Accordingly, in order to minimize a stress concentrated on the plurality of link lines LL and a crack caused thereby, a shape of the plurality of link lines LL may be various shapes including the above-mentioned shapes, but the exemplary embodiments of the present disclosure are not limited thereto.

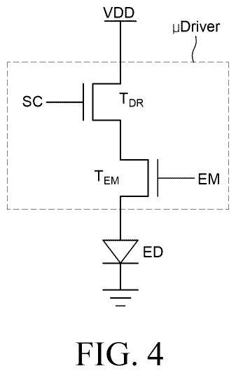

FIG. 4 is a view illustrating a circuit structure according to an exemplary embodiment of the present disclosure.

A pixel driving circuit PD may include a micro driver (μDriver). The micro LED (ED) is electrically connected to the micro driver (μDriver) of the pixel driving circuit PD to be driven. Even though in FIG. 4, it is illustrated that one micro LED (ED) is connected to one micro driver (μDriver), but the present disclosure is not limited thereto. For example, eight micro LEDs (ED) may be connected to one micro driver (μDriver). As another example, 16 micro LEDs (ED) may be connected to one micro driver (μDriver) or 32 micro LEDs (ED) or 64 micro LEDs (ED) may be simultaneously connected to one micro driver (μDriver). The micro LED (ED) may be a micro LED (μLED).

One micro driver (μDriver) may include a driving transistor T_{DR} and an emission transistor T_{EM}, but the exemplary embodiments of the present disclosure are not limited thereto.

For example, a high potential power voltage VDD may be applied to a first electrode of the driving transistor T_{DR} and a first electrode of the emission transistor T_{EM} may be connected to a second electrode of the driving transistor T_{DR}, and a scan signal SC may be applied to a gate electrode of the driving transistor T_{DR}. The scan signal SC applied to the gate electrode of the driving transistor T_{DR} is a direct current (DC) power and a fixed reference voltage may be applied in every frame, but the exemplary embodiments of the present disclosure are not limited thereto.

The second electrode of the driving transistor T_{DR} may be connected to a first electrode of the emission transistor T_{EM}, the micro LED (ED) may be connected to a second electrode of the emission transistor T_{EM}, and the emission signal EM may be applied to a gate electrode of the emission transistor T_{EM}. The emission signal EM applied to the gate electrode of the emission transistor T_{EM} may be a pulse width modulation signal which changes in every frame, but the exemplary embodiments of the present disclosure are not limited thereto.

A first electrode of the micro LED (ED) may be connected to the second electrode of the emission transistor T_{EM} and a second electrode of the micro LED (ED) may be connected to the ground. For example, the first electrode of the micro LED (ED) may be an anode electrode and the second electrode of the micro LED (ED) may be a cathode electrode, but the exemplary embodiments of the present disclosure are not limited thereto.

Each of the driving transistor T_{DR} and the emission transistor T_{EM} may be an n type transistor or a p type transistor.

The driving transistor T_{DR} may be turned on by a scan signal SC applied from the timing controller to the micro driver (μDriver) and the emission transistor T_{EM} may be turned on by the emission signal EM. By doing this, the driving current is applied to the micro LED (ED) via the driving transistor T_{DR} and the emission transistor T_{EM} by the high potential power voltage VDD applied to the first electrode of the driving transistor T_{DR} so that the micro LED (ED) may emit light.

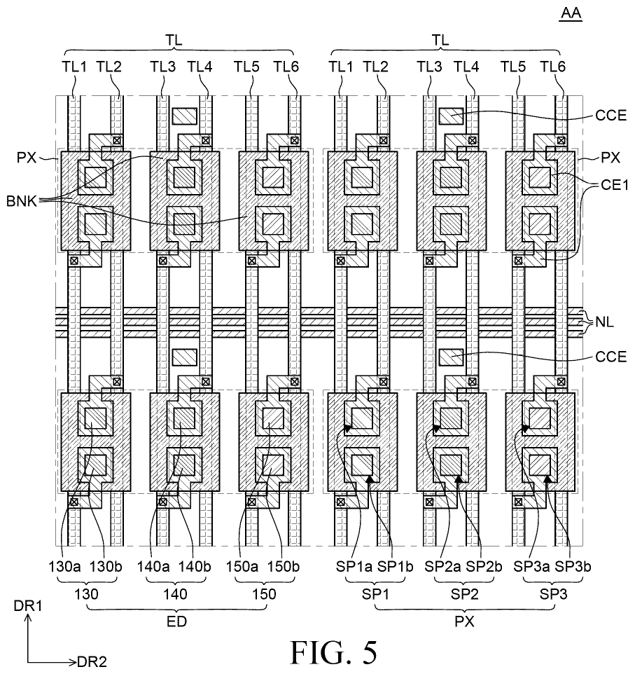

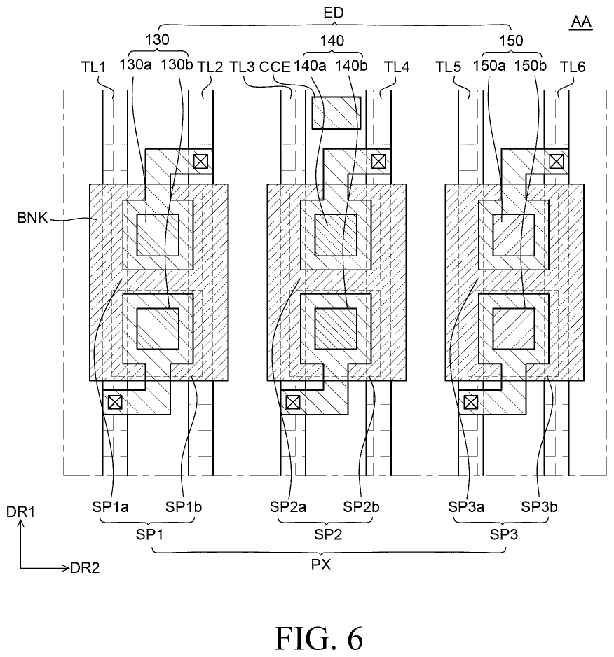

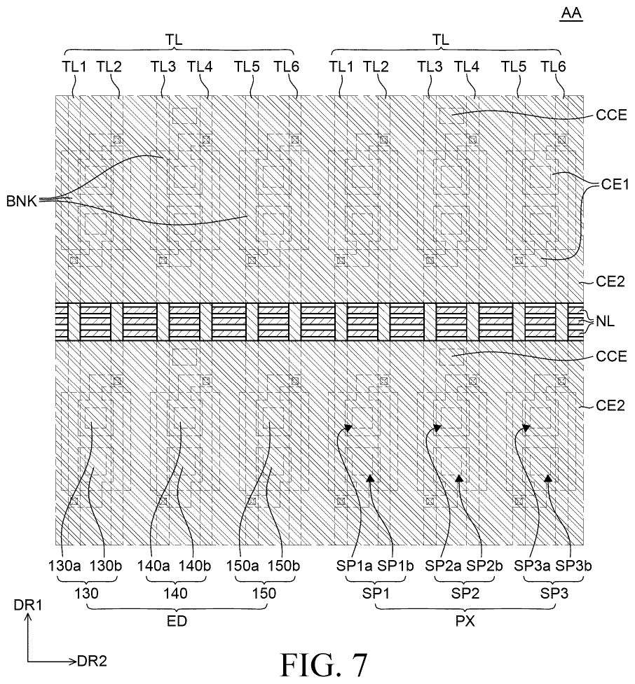

FIGS. 5 to 7 are plan views of a display apparatus according to an exemplary embodiment of the present disclosure. For example, FIG. 5 is an enlarged plan view of an active area including a plurality of pixels. For example, FIG. 6 is an enlarged plan view of an active area including one pixel. For example, FIG. 7 is an enlarged plan view of an active area including a plurality of pixels. In FIGS. 5 and 6, only a plurality of signal lines TL, a plurality of communication lines NL, a plurality of first electrodes CE1, a plurality of contact electrodes CCE, a plurality of banks BNK, and a plurality of micro LEDs (ED) are illustrated, but the exemplary embodiments of the present disclosure are not limited thereto. FIG. 7 is an enlarged plan view in which a plurality of second electrodes CE2 is additionally disposed to FIG. 5.

Referring to FIGS. 5 and 6, a plurality of pixels PX which is configured by a plurality of sub pixels may be disposed in the active area AA. Each of the plurality of sub pixels includes a micro LED (ED) and independently may emit light. The plurality of sub pixels may be disposed in a matrix by forming a plurality of rows and a plurality of columns, but the exemplary embodiments of the present disclosure are not limited thereto.

The plurality of sub pixels may include a first sub pixel SP1, a second sub pixel SP2, and a third sub pixel SP3. For example, any one of the first sub pixel SP1, the second sub pixel SP2, and the third sub pixel SP3 may be a red sub pixel, another may be a green sub pixel, and the third may be a blue sub pixel. The types of the plurality of sub pixels are illustrative, but the exemplary embodiments of the present disclosure are not limited thereto.

Each of the plurality of pixels PX may include one or more first sub pixels SP1, one or more second sub pixels SP2, and one or more third sub pixels SP3. For example, one pixel PX may include one pair of first sub pixels SP1, one pair of second sub pixels SP2, and one pair of third sub pixels SP3. One pair of first sub pixels SP1 may be configured by a 1-1-th sub pixel SP1a and a 1-2-th sub pixel SP1b. One pair of second sub pixels SP2 may be configured by a 2-1-th sub pixel SP2a and a 2-2-th sub pixel SP2b. One pair of third sub pixels SP3 may be configured by a 3-1-th sub pixel SP3a and a 3-2-th sub pixel SP3b. For example, one pixel PX may include a 1-1-th sub pixel SP1a and a 1-2-th sub pixel SP1b, a 2-1-th sub pixel SP2a and a 2-2-th sub pixel SP2b, and a 3-1-th sub pixel SP3a and a 3-2-th sub pixel SP3b, but the exemplary embodiments of the present disclosure are not limited thereto.

The plurality of sub pixels which forms one pixel PX may be disposed in various ways. For example, in one pixel PX, one pair of first sub pixels SP1 may be disposed on the same column, one pair of second sub pixels SP2 may be disposed on the same column, and one pair of third sub pixels SP3 may be disposed on the same column. The first sub pixels SP1, the second sub pixels SP2, and the third sub pixels SP3 may be disposed on the same row. A number and a placement of the plurality of sub pixels which configures one pixel PX are illustrative, but the exemplary embodiments of the present disclosure are not limited thereto.

The plurality of signal lines TL may be disposed in an area between the plurality of sub pixels. The plurality of signal lines TL may extend in the column direction between the plurality of sub pixels. The plurality of signal lines TL may be wiring lines which transmit an anode voltage from the pixel driving circuit PD to the plurality of sub pixels. For example, the plurality of signal lines TL may be electrically connected to the plurality of pixel driving circuits PD and the first electrodes CE1 of the plurality of sub pixels. The anode voltage output from the pixel driving circuit PD may be transmitted to the first electrode CE1 of the plurality of sub pixels through the plurality of signal lines TL. For example, the first electrode CE1 may be an electrode which is electrically connected to the anode electrode 134 of the micro LED (ED). Therefore, the anode voltage from the signal line TL may be transmitted to the anode electrode 134 of the micro LED (ED) through the first electrode CE1.

Accordingly, instead of the plurality of transistors and storage capacitors formed in each of the plurality of sub pixels, a pixel driving circuit PD in which a plurality of pixel circuits is integrated is used to simplify the structure of the display apparatus 1000. Further, a circuit which is disposed in each of the plurality of sub pixels is integrated in one pixel driving circuit PD so that highly efficient low power driving may be possible.

The plurality of signal lines TL may include a first signal line TL1, a second signal line TL2, a third signal line TL3, a fourth signal line TL4, a fifth signal line TL5, and a sixth signal line TL6.

The plurality of signal lines TL may be electrically connected to sub pixels disposed in a first direction DR1, among the plurality of sub pixels. For example, the first signal line TL1 and the second signal line TL2 may be electrically connected to the plurality of first sub pixels SP1 disposed in the first direction DR1, respectively. The third signal line TL3 and the fourth signal line TL1 may be electrically connected to a plurality of second sub pixels SP2 disposed in the first direction DR1, respectively. The fifth signal line TL5 and the sixth signal line TL6 may be electrically connected to a plurality of third sub pixels SP3 disposed in the first direction DR1, respectively.

Further, the plurality of signal lines TL may be electrically connected to a micro LED (ED) disposed in the first direction DR1, among the plurality of micro LEDs (ED). For example, one pair of signal line TL, among the plurality of signal lines TL, may be electrically connected to a plurality of micro LEDs (ED) which emits the same light, among the plurality of micro LEDs (ED). Specifically, the first signal line TL1 and the second signal line TL2 may be electrically connected to red micro LEDs disposed in the first direction DR1, respectively. The third signal line TL3 and the fourth signal line TL4 may be electrically connected to green micro LEDs disposed in the first direction DR1, respectively. The fifth signal line TL5 and the sixth signal line TL6 may be electrically connected to blue micro LEDs disposed in the first direction DR1, respectively.

The plurality of signal lines TL may be disposed to be spaced apart from each other along the second direction DR2. For example, one pair of signal lines TL, among the plurality of signal lines TL may be disposed on both sides of one pair of sub pixels. For example, the first signal line TL1 may be disposed on one of one pair of first sub pixels SP1 and the second signal line TL2 may be disposed on the other one of one pair of first sub pixels SP1. The first signal line TL1 may be electrically connected to one first sub pixel SP1, between one pair of first sub pixels SP1, for example, to the first electrode CE1 of the 1-2-th sub pixel SP1b. The second signal line TL2 may be electrically connected to the other first sub pixel SP1, between one pair of first sub pixels SP1, for example, to the first electrode CE1 of the 1-1-th sub pixel SP1a.

The third signal line TL3 may be disposed on one of one pair of second sub pixels SP2 and the fourth signal line TL4 may be disposed on the other one of one pair of second sub pixels SP2. For example, the third signal line TL3 may be disposed to be adjacent to the second signal line TL2. The third signal line TL3 may be electrically connected to one second sub pixel SP2, between one pair of second sub pixels SP2, for example, to the first electrode CE1 of the 2-2-th sub pixel SP2b. The fourth signal line TL4 may be electrically connected to the other second sub pixel SP2, between one pair of second sub pixels SP2, for example, to the first electrode CE1 of the 2-1-th sub pixel SP2a.

The fifth signal line TL5 may be disposed on one of one pair of third sub pixels SP3 and the sixth signal line TL6 may be disposed on the other one of one pair of third sub pixels SP3. For example, the fifth signal line TL5 may be disposed to be adjacent to the fourth signal line TL4. The sixth signal line TL6 may be disposed to be adjacent to the first signal line TL1 connected to the adjacent pixel PX. The fifth signal line TL5 may be electrically connected to one third sub pixel SP3, between one pair of third sub pixels SP3, for example, to the first electrode CE1 of the 3-2-th sub pixel SP3b. The sixth signal line TL6 may be electrically connected to the other third sub pixel SP3, between one pair of third sub pixels SP3, for example, to the first electrode CE1 of the 3-1-th sub pixel SP3a.

Each of the plurality of banks BNK may have a short axis along the second direction DR2. Therefore, the plurality of signal lines TL may be disposed to be spaced apart from each other along the short axis direction of the plurality of banks BNK. For example, the first signal line TL1, the second signal line TL2, the third signal line TL3, the fourth signal line TL4, the fifth signal line TL5, and the sixth signal line TL6 may be disposed to be adjacent to each other along the second direction DR2.

Each of the plurality of signal lines TL may be disposed to overlap the plurality of banks BNK. For example, each of the plurality of signal lines TL may be disposed to overlap the bank BNK disposed along the first direction DR1.

For example, the first signal line TL1 and the second signal line TL2 may overlap the plurality of banks BNK in which one pair of first sub pixels SP1 is disposed. The third signal line TL3 and the fourth signal line TL4 may overlap the plurality of banks BNK in which one pair of second sub pixels SP2 is disposed. The fifth signal line TL5 and the sixth signal line TL6 may overlap the plurality of banks BNK in which one pair of third sub pixels SP3 is disposed.

In the meantime, an interval between one pair of signal lines TL may be smaller than a length of the short axis of each of the plurality of banks BNK. Further, one pair of signal lines TL, among the plurality of signal lines TL, may overlap the same bank BNK.

For example, an interval between the first signal line TL1 and the second signal line TL2 may be shorter than a length of the short axis of the bank BNK in which one pair of first sub pixels SP1 is disposed. Therefore, the first signal line TL1 and the second signal line TL2 may overlap the same bank BNK. For example, the first signal line TL1 and the second signal line TL2 may overlap the plurality of banks BNK in which one pair of first sub pixels SP1 is disposed.

For example, an interval between the third signal line TL3 and the fourth signal line TL4 may be shorter than a length of the short axis of the bank BNK in which one pair of second sub pixels SP2 is disposed. Therefore, the third signal line TL3 and the fourth signal line TL4 may overlap the same bank BNK. For example, the third signal line TL3 and the fourth signal line TL4 may overlap the plurality of banks BNK in which one pair of second sub pixels SP2 is disposed.

For example, an interval between the fifth signal line TL5 and the sixth signal line TL6 may be shorter than a length of the short axis of the bank BNK in which one pair of third sub pixels SP3 is disposed. Therefore, the fifth signal line TL5 and the sixth signal line TL6 may overlap the same bank BNK. For example, the fifth signal line TL5 and the sixth signal line TL6 may overlap the plurality of banks BNK in which one pair of third sub pixels SP3 is disposed.

In the meantime, the plurality of signal line TL may be disposed in an area excluding an area between banks BNK adjacent in the second direction DR2, among the plurality of banks BNK. For example, the bank BNK of the first sub pixel SP1, the bank BNK of the second sub pixel SP2, and the bank BNK of the third sub pixel SP3 may be configured to be separated from each other along the second direction DR2. At this time, the plurality of signal lines TL may be not disposed between the bank BNK of the first sub pixel SP1 and the bank BNK of the second sub pixel SP2, may be not disposed between the bank of the second sub pixel SP2 and the bank BNK of the third sub pixel SP3, and may be not disposed between the bank BNK of the third sub pixel SP3 and the bank BNK of the first sub pixel SP1.

The plurality of signal lines TL may be formed of a conductive material. For example, the plurality of signal lines TL may be configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the exemplary embodiments of the present disclosure are not limited thereto. As another example, the plurality of signal lines TL may be formed with a multi-layered structure of conductive materials. For example, the plurality of signal lines TL may be formed with a multi-layered structure of titanium (Ti)/aluminum (Al)/titanium (Ti)/indium tin oxide (ITO), but the exemplary embodiments of the present disclosure are not limited thereto.

A plurality of communication lines NL may be disposed in an area between the plurality of pixels PX. The plurality of communication lines NL may be disposed to extend in the second direction DR2 in an area between the plurality of pixels PX. For example, referring to FIG. 7, the plurality of communication lines NL extends in a row direction. The plurality of communication lines NL may be disposed in the area between the plurality of second electrodes CE2 and may not overlap the plurality of second electrodes CE2. For example, the plurality of communication lines NL may be wiring lines used for short distance communication, such as near field communication (NFC). The plurality of communication lines NL may serve as antennas. For example, the plurality of communication lines NL may be a plurality of connection lines, but the exemplary embodiments of the present disclosure are not limited thereto.

According to the present disclosure, a bank BNK may be disposed in each of the plurality of sub pixels. The plurality of banks BNK may be structures in which the plurality of micro LEDs (ED) is seated. The plurality of banks BNK may guide a position of the plurality of micro LEDs (ED) during a transfer process of transferring the plurality of micro LEDs (ED) to the display apparatus 1000. The plurality of micro LEDs (ED) may be transferred onto the plurality of banks BNK in the transfer process of the plurality of micro LEDs (ED). The plurality of banks BNK may be bank patterns or structures, but the exemplary embodiments of the present disclosure are not limited thereto.

A bank BNK of the first sub pixel SP1, a bank BNK of the second sub pixel SP2, and a bank BNK of the third sub pixel SP3 may be disposed to be spaced apart from each other. The bank BNK of the first sub pixel SP1, the bank BNK of the second sub pixel SP2, and the bank BNK of the third sub pixel SP3 may be configured to be separated from each other along the second direction DR2. Therefore, the banks BNK of the first sub pixel SP1, the second sub pixel SP2, and the third sub pixel SP3 to which different types of micro LEDs (ED) are transferred may be easily identified.

The bank BNK of the 1-1-th sub pixel SP1a and the bank BNK of the 1-2-th sub pixel SP1b may be connected to each other. The bank BNK of the 2-1-th sub pixel SP2a and the bank BNK of the 2-2-th sub pixel SP2b may be connected to each other. The bank BNK of the 3-1-th sub pixel SP3a and the bank BNK of the 3-2-th sub pixel SP3b may be connected to each other.

For example, one pair of micro LEDs (ED) which emit the same color light may be disposed in each of the plurality of banks BNK along the first direction DR1. A 1-1-th micro LED 130a and a 1-2-th micro LED 130b may be disposed on one bank BNK, among the plurality of banks BNK, along the first direction DR1. A 2-1-th micro LED 140a and a 2-2-th micro LED 140b may be disposed on another bank BNK, among the plurality of banks BNK, along the first direction DR1. A 3-1-th micro LED 150a and a 3-2-th micro LED 150b may be disposed on the third bank BNK, among the plurality of banks BNK, along the first direction DR1.

In the meantime, each of the plurality of banks BNK may have a long axis along a direction in which the micro LED (ED) is disposed. For example, the bank BNK of the first sub pixel SP1 may have a long axis along the first direction DR1 in which the 1-1-th micro LED 130a and the 1-2-th micro LED 130b are disposed. The bank BNK of the second sub pixel SP2 may have a long axis along the first direction DR1 in which the 2-1-th micro LED 140a and the 2-2-th micro LED 140b are disposed. The bank BNK of the third sub pixel SP3 may have a long axis along the first direction DR1 in which the 3-1-th micro LED 150a and the 3-2-th micro LED 150b are disposed.

However, in consideration of a design, such as a transfer process requirement, the bank BNK of the 1-1-th sub pixel SP1a and the bank BNK of the 1-2-th sub pixel SP1b in which the same type of micro LED (ED) is disposed may be spaced apart or separated from each other. The bank BNK of the 2-1-th sub pixel SP2a and the bank BNK of the 2-2-th sub pixel SP2b may be spaced apart or separated from each other. The bank BNK of the 3-1-th sub pixel SP3a and the bank BNK of the 3-2-th sub pixel SP3b may be spaced apart or separated from each other. Accordingly, the banks BNK of one pair of first sub pixels SP1, the banks BNK of one pair of second sub pixels SP2, and the banks BNK of one pair of third sub pixels SP3 may be formed in various forms, but the exemplary embodiments of the present disclosure are not limited thereto.

For example, the plurality of banks BNK may be formed of an organic insulating material. The plurality of banks BNK may be configured by a single layer or a double layer of an organic insulating material. For example, the plurality of banks BNK may be configured by a photo resist, polyimide (PI), or acrylic material, but the exemplary embodiments of the present disclosure are not limited thereto.

In the meantime, each of the plurality of banks BNK may overlap the signal line TL disposed below the plurality of banks BNK. Further, one bank BNK among the plurality of banks BNK may overlap one pair of signal lines TL. For example, one pair of first sub pixels SP1 may be disposed on one bank and the bank BNK on which one pair of first sub pixels SP1 is disposed may overlap the first signal line TL1 and the second signal line TL2. Further, one pair of second sub pixels SP2 may be disposed on one bank and the bank BNK on which one pair of second sub pixels SP2 is disposed may overlap the third signal line TL3 and the fourth signal line TL4. Further, one pair of third sub pixels SP3 may be disposed on one bank and the bank BNK on which one pair of third sub pixels SP3 is disposed may overlap the fifth signal line TL5 and the sixth signal line TL6.

The first electrode CE1 may be disposed in each of the plurality of sub pixels. The first electrode CE1 may be disposed on the bank BNK. For example, each of the plurality of first electrodes CE1 may be disposed on a top surface and a side surface of each of the plurality of banks BNK.

The first electrode CE1 may be electrically connected to one signal line TL, among the plurality of signal lines TL. At least a part of the first electrode CE1 extends to the outside of the bank BNK to be electrically connected to the signal line TL which is the most adjacent to the first electrode CE1. For example, a part of the first electrode CE1 of the 1-1-th sub pixel SP1a extends to one area of the 1-1-th sub pixel SP1a to be electrically connected to the first signal line TL2. A part of the first electrode CE1 of the 1-2-th sub pixel SP1b extends to the other area of the 1-2-th sub pixel SP1b to be electrically connected to the second signal line TL1. A part of the first electrode CE1 of the 2-1-th sub pixel SP2a extends to one area of the 2-1-th sub pixel SP2a to be electrically connected to the third signal line TL4. A part of the first electrode CE1 of the 2-2-th sub pixel SP2b extends to the other area of the 2-2-th sub pixel SP2b to be electrically connected to the fourth signal line TL3. A part of the first electrode CE1 of the 3-1-th sub pixel SP3a extends to one area of the 3-1-th sub pixel SP3a to be electrically connected to the fifth signal line TL6. A part of the first electrode CE1 of the 3-2-th sub pixel SP3b extends to the other area of the 3-2-th sub pixel SP3b to be electrically connected to the sixth signal line TL5.

The first electrode CE1 is electrically connected to the anode electrode 134 of the micro LED (ED) and may transmit an anode voltage from the pixel driving circuit PD to the micro LED (ED) through the signal line TL. Different voltages may be applied to the first electrodes CE1 of the plurality of sub pixels depending on the image to be displayed. For example, different voltages may be applied to the first electrodes CE1 of the plurality of sub pixels. Therefore, the first electrode CE1 may be a pixel electrode, but the exemplary embodiments of the present disclosure are not limited thereto.

The first electrode CE1 may be configured by a conductive material. For example, the first electrode CE1 may be configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the exemplary embodiments of the present disclosure are not limited thereto. As another example, the first electrode CE1 may be configured by a multi-layered structure of conductive materials. For example, the plurality of first electrodes CE1 may be configured by a multi-layered structure of titanium (Ti)/aluminum (Al)/titanium (Ti)/indium tin oxide (ITO), but the exemplary embodiments of the present disclosure are not limited thereto.

Each of the plurality of first electrodes CE1 may include a first part and a second part disposed on the plurality of banks BNK and a third part extending to the outside of the plurality of banks BNK.

The first part may be electrically connected to the micro LED (ED) disposed on the plurality of banks BNK. The third part may be electrically connected to the plurality of signal lines TL. The second part may electrically connect the first part and the third part.

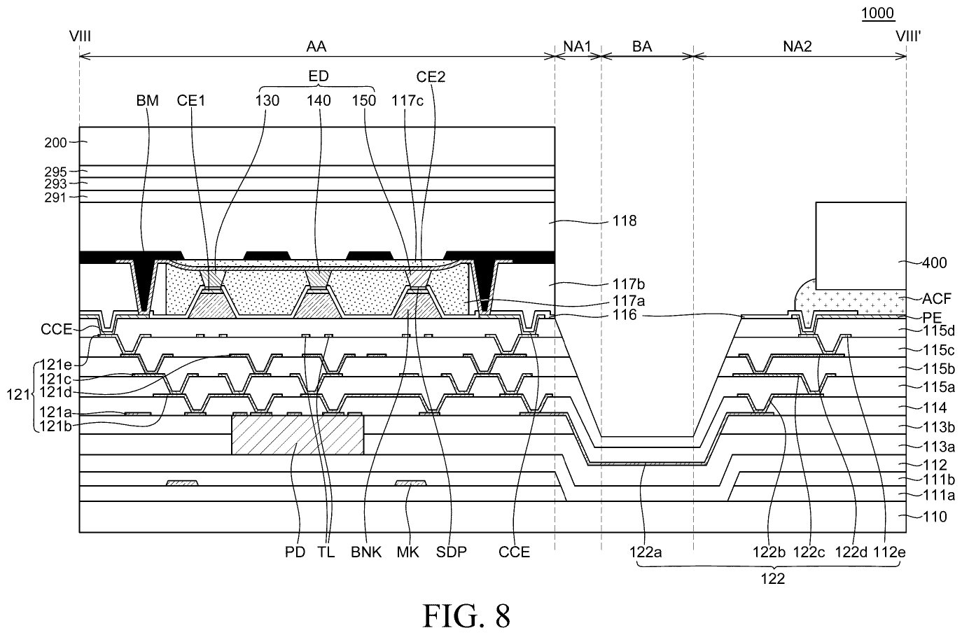

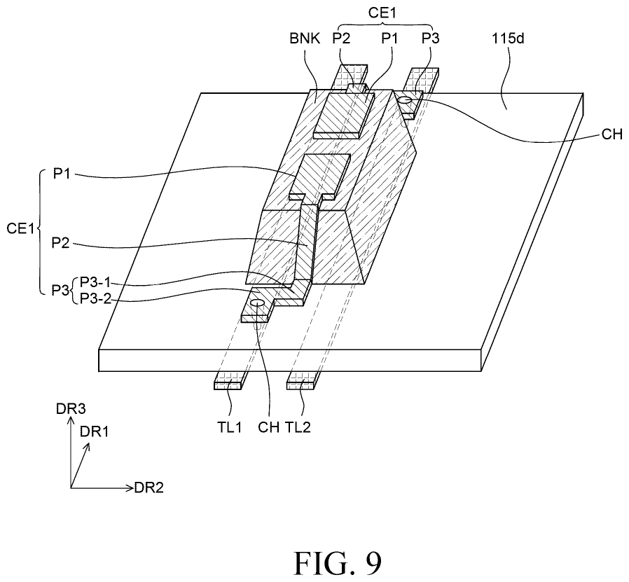

The plurality of first electrodes CE1 will be described in detail below with reference to FIGS. 8 and 9.

The micro LED (ED) may be disposed in each of the plurality of sub pixels. The plurality of micro LEDs (ED) may be any one of a light-emitting diode (LED) or a micro light-emitting diode (micro LED), but the exemplary embodiments of the present disclosure are not limited thereto. The plurality of micro LEDs (ED) may be disposed on the bank BNK and the first electrode CE1. The plurality of micro LEDs (ED) is disposed on the first electrode CE1 and may be electrically connected to the first electrode CE1. Accordingly, the micro LED (ED) is applied with an anode voltage from the pixel driving circuit PD through the signal line TL and the first electrode CE1 to emit light.

The plurality of micro LEDs (ED) may include a first micro LED 130, a second micro LED 140, and a third micro LED 150. The first micro LED 130 may be disposed in the first sub pixel SP1. The second micro LED 140 may be disposed in the second sub pixel SP2. The third micro LED 150 may be disposed in the third sub pixel SP3. For example, any one of the first micro LED 130, the second micro LED 140, and the third micro LED 150 may be a red micro LED, another may be a green micro LED, and the third may be a blue micro LED, but the exemplary embodiments of the present disclosure are not limited thereto. Therefore, red light, green light, and blue light emitted from the plurality of micro LEDs (ED) are combined to implement various color light including white. The types of the plurality of micro LEDs (ED) are illustrative, but the exemplary embodiments of the present disclosure are not limited thereto.

The first micro LED 130 may include a 1-1-th micro LED 130a disposed in the 1-1-th sub pixel SP1a and a 1-2-th micro LED 130b disposed in the 1-2-th sub pixel SP1b. The second micro LED 140 may include a 2-1-th micro LED 140a disposed in the 2-1-th sub pixel SP2a and a 2-2-th micro LED 140b disposed in the 2-2-th sub pixel SP2b. The third micro LED 150 may include a 3-1-th micro LED 150a disposed in the 3-1-th sub pixel SP3a and a 3-2-th micro LED 150b disposed in the 3-2-th sub pixel SP3b.

Referring to FIGS. 5, 6 and 7 together, the second electrode CE2 may be disposed in each of the plurality of sub pixels. The second electrode CE2 may be disposed on the micro LED (ED). The second electrode CE2 may be electrically connected to the pixel driving circuit PD through the plurality of contact electrodes CCE.

For example, the second electrode CE2 is electrically connected to the cathode electrode 135 of the micro LED (ED) to transmit a cathode voltage from the pixel driving circuit PD to the micro LED (ED). The same cathode voltage may be applied to the second electrodes CE2 of the plurality of sub pixels. For example, the same voltage may be applied to the second electrode CE2 of each of the plurality of sub pixels and the cathode electrode 135 of the micro LED (ED). Therefore, the second electrode CE2 may be a common electrode, but the exemplary embodiments of the present disclosure are not limited thereto.

At least some of the plurality of sub pixel may share the second electrode CE2. At least some of the second electrodes CE2 of the plurality of sub pixels may be electrically connected to each other. As the same voltage is applied to the second electrode CE2, the second electrodes CE2 of at least some of sub pixels are shared. For example, the second electrodes CE2 of at least some pixels PX, among the plurality of pixels PX disposed on the same row, may be connected to each other. For example, one second electrode CE2 may be disposed in the plurality of pixels PX. One second electrode CE2 may be disposed in every n sub pixels.

For example, some of the second electrodes CE2 of the plurality of sub pixels may be spaced apart or separated from each other. For example, a second electrode CE2 connected to pixels PX in a n-th row and a second electrode CE2 connected to pixels PX in a n+1-th row may be spaced apart or separated from each other. For example, the plurality of second electrodes CE2 may be spaced apart from each other with the plurality of communication lines NL extending in the second direction DR2 therebetween. Accordingly, the number of the plurality of sub pixels may be larger than the number of the plurality of second electrodes CE2. As another example, all the second electrodes CE2 of the plurality of sub pixels are connected to each other so that only one second electrode CE2 may be disposed on the substrate 110, but the exemplary embodiments of the present disclosure are not limited thereto.

The plurality of second electrodes CE2 may be configured by a transparent conductive material, but the exemplary embodiments of the present disclosure are not limited thereto. The plurality of second electrodes CE2 is configured by a transparent conductive material so that light emitted from the micro LED (ED) travels toward the top of the second electrode CE2. For example, the second electrode CE2 may be configured by a transparent conductive material, such as indium tin oxide (ITO), indium zinc oxide (IZO), indium gallium zinc oxide (IGZO), but the exemplary embodiments of the present disclosure are not limited thereto.

A plurality of contact electrodes CCE may be disposed on the substrate 110. For example, the plurality of contact electrodes CCE may be disposed to be spaced apart from the plurality of banks BNK and the plurality of signal lines TL. Each of the plurality of second electrodes CE2 may overlap at least one contact electrode CCE. For example, one second electrode CE2 may overlap a plurality of contact electrodes CCE.

For example, the plurality of contact electrodes CCE may be electrically connected to the plurality of second electrodes CE2. The plurality of contact electrodes CCE is disposed between the substrate 110 and the plurality of second electrodes CE2 to transmit a cathode voltage from the pixel driving circuit PD to the second electrode CE2.

For example, when a micro LED (ED) is used as the micro LED (ED), a plurality of micro LEDs is formed on a wafer and the micro LED is transferred onto the substrate 110 of the display apparatus 1000 to manufacture the display apparatus 1000. However, during the process of transferring the plurality of micro LEDs (ED) having a micro size from the wafer to the substrate 110, various defects may be caused. For example, in some sub pixel, a non-transfer defect in which the micro LED is not transferred may occur and in the other sub pixel, a defect that the micro LED (ED) is transferred in a wrong position may occur due to the alignment error. Further, even though the transfer process is normally performed, the transferred micro LED (ED) may be defective. Accordingly, in consideration of the defects during the transfer process of the plurality of micro LEDs (ED), a plurality of micro LEDs which emits the same color light may be transferred into one sub pixel. A lighting test for the plurality of micro LEDs (ED) is performed and only one micro LED (ED) which is finally determined to be normal may be used.

For example, the 1-1-th micro LED 130a and the 1-2-th micro LED 130b are transferred to one pixel PX together and defects thereof may be tested. If both the 1-1-th micro LED 130a and the 1-2-th micro LED 130b are determined to be normal, only the 1-1-th micro LED 130a is used, but the 1-2-th micro LED 130b may be not used. As another example, if only the 1-2-th micro LED 130b between the 1-1-th micro LED 130a and the 1-2-th micro LED 130b is determined to be normal, the 1-1-th micro LED 130a is not used, but only the 1-2-th micro LED 130b may be used. Accordingly, even though the plurality of micro LEDs (ED) which emits the same color light is transferred into one pixel PX, finally, only one micro LED (ED) may be used.

Therefore, any one of one pair of micro LEDs (ED) is a main (or primary) micro LED (ED) and the other micro LED (ED) may be a redundancy micro LED (ED). The redundancy micro LED (ED) may be an extra micro LED (ED) which is transferred to prepare for a defect of the main micro LED (ED). When the main micro LED (ED) is defective, the redundancy micro LED (ED) may be used instead. Accordingly, the main micro LED (ED) and the redundancy micro LED (ED) are transferred together to one pixel PX so that the degradation of the display quality due to the defects of the main micro LED (ED) and the redundancy micro LED (ED) may be minimized.

For example, a 1-1-th micro LED 130a, a 2-1-th micro LED 140a, and a 3-1-th micro LED 150a which are transferred into one pixel PX are used as main micro LEDs (ED) and a 1-2-th micro LED 130b, a 2-2-th micro LED 140b, and a 3-2-th micro LED 150b may be used as redundancy micro LEDs (ED).

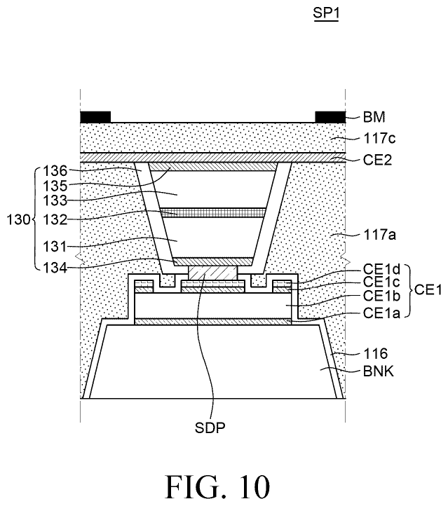

FIG. 8 is a cross-sectional view taken along the line VIII-VIII′ of FIG. 3. FIG. 9 is an enlarged perspective view of a display apparatus according to an exemplary embodiment of the present disclosure. FIG. 10 is a cross-sectional view of a display apparatus according to an exemplary embodiment of the present disclosure. FIG. 8 is a cross-sectional view of a display apparatus according to an exemplary embodiment of the present disclosure. For example, FIG. 8 is a cross-sectional view of an active area AA, a first non-active area NA1, a bending area BA, and a second non-active area NA2. For example, FIG. 9 is an enlarged perspective view of a first sub pixel SP1. For example, FIG. 10 is an enlarged cross-sectional view of a first sub pixel SP1. In the meantime, for the convenience of illustration, in FIG. 3, it is illustrated that a cross-sectional line of VIII-VIII′ and a driving line VL and a link line LL do not overlap, but the cross-sectional line VIII-VIII′ of FIG. 3 is provided to represent the same position as the adjacent driving line VL and link line LL. In FIG. 9, only the first signal line TL1, the second signal line TL2, the fourth insulating layer 115d, the first electrode CE1, and the bank BNK are schematically illustrated. However, for the convenience of description, it is illustrated that both ends of the first signal line TL1 and the second signal line TL2 extend to outside of the fourth insulating layer 115d, but the exemplary embodiments of the present disclosure are not limited thereto.

Referring to FIG. 8, a first buffer layer 111a and a second buffer layer 111b may be disposed in the remaining area of the substrate 110 excluding the bending area BA.

The first buffer layer 111a and the second buffer layer 111b may be disposed in the active area AA, the first non-active area NA1, and the second non-active area NA2. The first buffer layer 111a and the second buffer layer 111b may reduce permeation of moisture or impurities through the substrate 110. The first buffer layer 111a and the second buffer layer 111b may be formed of an inorganic insulating material. For example, the first buffer layer 111a and the second buffer layer 111b may be configured by a single layer or multiple layers of silicon oxide (SiOx) or silicon nitride (SiNx), but the exemplary embodiments of the present disclosure are not limited thereto.

For example, the first buffer layer 111a and the second buffer layer 111b on the bending area BA may be partially removed. A top surface of the substrate 110 located in the bending area BA may be exposed from the first buffer layer 111a and the second buffer layer 111b. The first buffer layer 111a and the second buffer layer 111b which are formed of an inorganic insulating material are removed from the bending area BA to minimize cracks of the first buffer layer 111a and the second buffer layer 111b which may be generated during the bending.

A plurality of alignment keys MK may be disposed between the first buffer layer 111a and the second buffer layer 111b. The plurality of alignment keys MK may be configured to identify a position of the pixel driving circuit PD during the manufacturing process of the display apparatus 1000. For example, the plurality of alignment keys MK may be configured to align a position of the pixel driving circuit PD which is transferred onto the adhesive layer 112. As another example, the plurality of alignment keys MK may be omitted.

The adhesive layer 112 may be disposed on the second buffer layer 111b. The adhesive layer 112 may be disposed in the active area AA, the first non-active area NA1, the bending area BA, and the second non-active area NA2. As another example, in the non-active area NA including the bending area BA, at least a part of the adhesive layer 112 may be removed. For example, the adhesive layer 112 may be formed of any one of adhesive polymer, epoxy resin, UV curable resin, polyimide based, acrylate based, urethane based, and polydimethylsiloxane (PDMS), but the exemplary embodiments of the present disclosure are not limited thereto.

The pixel driving circuit PD may be disposed on the adhesive layer 112 in the active area AA. When the pixel driving circuit PD is implemented as a driving driver, the driving driver may be mounted on the adhesive layer 112 by the transfer process, but the exemplary embodiments of the present disclosure are not limited thereto.

A first protection layer 113a and a second protection layer 113b may be disposed on the adhesive layer 112 and the pixel driving circuit PD. For example, the first protection layer 113a and the second protection layer 113b may be disposed so as to enclose the side surface of the pixel driving circuit PD, but the exemplary embodiments of the present disclosure are not limited thereto. For example, the second protection layer 113b may be disposed so as to cover at least a part of a top surface of the pixel driving circuit PD. For example, at least one of the first protection layer 113a and the second protection layer 113b of the protection layer 113 disposed on the bending area BA may be omitted. For example, the first protection layer 113a is entirely disposed in the active area AA and the non-active area NA and the second protection layer 113b may be partially disposed in the active area AA, the first non-active area NA1, and the second non-active area NA2. For example, a part of the second protection layer 113b in the bending area BA may be removed, but the exemplary embodiments of the present disclosure are not limited thereto.

The first protection layer 113a and the second protection layer 113b may be configured by an organic insulating material, but the exemplary embodiments of the present disclosure are not limited thereto. For example, the first protection layer 113a and the second protection layer 113b may be configured by a photo resist, polyimide (PI), or photo acrylic material, but the exemplary embodiments of the present disclosure are not limited thereto. For example, the first protection layer 113a and the second protection layer 113b may be over coating layers or insulating layers, but the exemplary embodiments of the present disclosure are not limited thereto.

According to the present disclosure, in the active area AA, the plurality of first connection lines 121 may be disposed on the second protection layer 113b. The plurality of first connection lines 121 may be wiring lines which electrically connect the pixel driving circuit PD to the other component. For example, the pixel driving circuit PD may be electrically connected to the plurality of signal lines TL and the plurality of contact electrodes CCE through the plurality of first connection lines 121. For example, the plurality of first connection lines 121 may include a 1-1-th connection line 121a, a 1-2-th connection line 121b, a 1-3-th connection line 121c, a 1-4-th connection line 121d, and a 1-5-th connection line 121e, but the exemplary embodiments of the present disclosure are not limited thereto. Each of the plurality of first connection lines 121 refers to a signal line disposed on the same layer and the plurality of first connection lines 121 may include signal lines to which different signals are applied.

For example, the plurality of 1-1-th connection lines 121a may be disposed on the second protection layer 113b. The plurality of 1-1-th connection lines 121a may be electrically connected to the pixel driving circuit PD. The plurality of 1-1-th connection lines 121a may transmit a voltage output from the pixel driving circuit PD to the first electrode CE1 or the second electrode CE2.

For example, a third protection layer 114 may be disposed on the second protection layer 113b. The third protection layer 114 may be entirely disposed in the active area AA and the non-active area NA. In the bending area BA, the third protection layer 114 may cover a side surface of the second protection layer 113b and the top surface of the first protection layer 113a. The third protection layer 114 may be configured by an organic insulating material. For example, the third protection layer 114 may be configured by a photo resist, polyimide (PI), or photo acrylic material, but the exemplary embodiments of the present disclosure are not limited thereto. For example, the first protection layer 113a, the second protection layer 113b, and the third protection layer 114 may be configured by the same material, the exemplary embodiments of the present disclosure are not limited thereto.

The plurality of 1-2-th connection lines 121b may be disposed on the third protection layer 114. The plurality of 1-2-th connection lines 121b may be indirectly or directly connected to the pixel driving circuit PD. For example, a part of the 1-2-th connection line 121b may be directly connected to the pixel driving circuit PD through a contact hole of the third protection layer 114. The other part of the 1-2-th connection line 121b may be electrically connected to the 1-1-th connection line 121a through the contact hole of the third protection layer 114, but the exemplary embodiment of the present disclosure are not limited thereto. A voltage output from the pixel driving circuit PD may be transmitted to the first electrode CE1 or the second electrode CE2 through a connection line other than the plurality of 1-2-th connection lines 121b.

The first insulating layer 115a may be disposed on the plurality of 1-2-th connection lines 121b. The first insulating layer 115a may be entirely disposed in the active area AA and the non-active area NA, but the exemplary embodiments of the present disclosure are not limited thereto. The first insulating layer 115a may be configured by an organic insulating material, but the exemplary embodiments of the present disclosure are not limited thereto. For example, the first insulating layer 115a may be configured by photo resist, polyimide (PI) or photo acryl based material, but the exemplary embodiments of the present disclosure are not limited thereto.

The plurality of 1-3-th connection lines 121c may be disposed on the first insulating layer 115a. The plurality of 1-3-th connection lines 121c may be electrically connected to the plurality of 1-2-th connection lines 121b. For example, the 1-3-th connection lines 121c may be electrically connected to the 1-2-th connection line 121b through a contact hole of the first insulating layer 115a.

The second insulating layer 115b may be disposed on the plurality of 1-3-th connection lines 121c. The second insulating layer 115b may be disposed in a remaining area excluding the bending area BA, but the exemplary embodiments of the present disclosure are not limited thereto. The second insulating layer 115b may be disposed in the active area AA, the first non-active area NA1, and the second non-active area NA2, but the exemplary embodiments of the present disclosure are not limited thereto. For example, a part of the second insulating layer 115b disposed in the bending area BA may be removed. The second insulating layer 115b may be configured by an organic insulating material, but the exemplary embodiments of the present disclosure are not limited thereto. For example, the second insulating layer 115b may be configured by a photo resist, polyimide (PI), or photo acrylic material, but the exemplary embodiments of the present disclosure are not limited thereto.

The plurality of 1-4-th connection lines 121d may be disposed on the second insulating layer 115b. The plurality of 1-4-th connection lines 121d may be electrically connected to the plurality of 1-3-th connection lines 121c. For example, the 1-4-th connection lines 121d may be electrically connected to the 1-3-th connection line 121c through a contact hole of the second insulating layer 115b.

The third insulating layer 115c may be disposed on the plurality of 1-4-th connection lines 121d. The third insulating layer 115c may be disposed in a remaining area excluding the bending area BA, but the exemplary embodiments of the present disclosure are not limited thereto. The third insulating layer 115c may be disposed in the active area AA, the first non-active area NA1, and the second non-active area NA2, but the exemplary embodiments of the present disclosure are not limited thereto. For example, a part of the third insulating layer 115c disposed in the bending area BA may be removed. The third insulating layer 115c may be configured by an organic insulating material, but the exemplary embodiments of the present disclosure are not limited thereto. For example, the third insulating layer 115c may be configured by a photo resist, polyimide (PI), or photo acrylic material, but the exemplary embodiments of the present disclosure are not limited thereto.

The plurality of 1-5-th connection lines 121e may be disposed on the third insulating layer 115c. The plurality of 1-5-th connection lines 121e may be electrically connected to the plurality of 1-4-th connection lines 121d. For example, the 1-5-th connection lines 121e may be electrically connected to the 1-4-th connection line 121d through a contact hole of the third insulating layer 115c.

A plurality of signal lines TL may be disposed on the third insulating layer 115c in the active area AA. The plurality of signal lines TL may be disposed to extend to an area between the plurality of banks BNK adjacent in the first direction DR1. For example, the plurality of signal lines TL may be disposed so as to overlap any one of the plurality of banks BNK. The plurality of signal lines TL may be disposed so as to overlap the plurality of banks BNK disposed in the first direction DR1. In the meantime, the plurality of signal lines TL may be not disposed in an area between the plurality of banks BNK adjacent in the second direction DR2.

The plurality of signal lines TL may be electrically connected to the plurality of first electrodes CE1. For example, the plurality of signal lines TL may be wiring lines which are in direct contact with the plurality of first electrodes CE1. Referring to FIG. 9 together, the plurality of signal lines TL may be connected to the plurality of first electrodes CE1 through a contact hole CH disposed in the fourth insulating layer 115d. At this time, the plurality of signal lines TL may be a conductive layer disposed to be adjacent to the plurality of first electrodes CE1, among the conductive layers disposed below the plurality of first electrodes CE1. In the meantime, the plurality of banks BNK may be disposed on the same layer as the plurality of first electrodes CE1. Accordingly, the plurality of signal lines TL may be a conductive layer disposed to be adjacent to the plurality of banks BNK, among the conductive layers disposed below the plurality of banks BNK.

According to the present disclosure, in the non-active area NA, the plurality of second connection lines 122 may be disposed on the second protection layer 113b. The plurality of second connection lines 122 may be wiring lines which transmit a signal transmitted from the flexible circuit board (or flexible film) 400 and the printed circuit board 500 (see FIG. 1) to the pad unit PAD to the pixel driving circuit PD of the active area AA. For example, the plurality of second connection lines 122 is electrically connected to the plurality of pad electrodes PE to be applied with a signal from the flexible circuit board (or flexible film) 400 and the printed circuit board 500. For example, the second connection lines 122 may transmit a signal which is transmitted to the pad unit PAD through the plurality of first connection lines 121 disposed in the active area AA to the pixel driving circuit PD.

For example, the plurality of second connection lines 122 extends toward the active area AA from the pad unit PAD to transmit a signal to the wiring line of the active area AA. In this case, the plurality of second connection lines 122 may serve as a link line LL. The plurality of second connection lines 122 may include a 2-1-th connection line 122a, a 2-2-th connection line 122b, a 2-3-th connection line 122c, a 2-4-th connection line 122d, and a 2-5-th connection line 122c.

The plurality of 2-1-th connection lines 122a may be disposed on the second protection layer 113b. The plurality of 2-1-th connection lines 122a may extend from the second non-active area NA2 to the bending area BA and the first non-active area NA1. The plurality of 2-1-th connection lines 122a may transmit a signal transmitted from the flexible circuit board (or flexible film) 400 and the printed circuit board 500 to the pad unit PAD to the pixel driving circuit PD of the active area AA.

The plurality of 2-2-th connection lines 122b may be disposed on the third protection layer 114. The plurality of 2-2-th connection lines 122b may be disposed in the second non-active area NA2. The 2-2-th connection line 122b may be electrically connected to the 2-1-th connection line 122a through the contact hole of the third protection layer 114. Accordingly, a signal from the flexible circuit board (or flexible film) 400 and the printed circuit board 500 may be transmitted to the 2-1-th connection line 122a through the 2-2-th connection line 122b.

The 2-3-th connection line 122c may be disposed on the first insulating layer 115a. The 2-3-th connection lines 122c may be disposed in the second non-active area NA2. The 2-3-th connection line 122c may be electrically connected to the 2-2-th connection line 122b through a contact hole of the first insulating layer 115a. Accordingly, a signal from the flexible circuit board (or flexible film) 400 and the printed circuit board 500 may be transmitted to the 2-1-th connection line 122a through the 2-3-th connection line 122c and the 2-2-th connection line 122b.

The 2-4-th connection line 122d may be disposed on the second insulating layer 115b. The 2-4-th connection line 122d may be disposed in the second non-active area NA2. The 2-4-th connection line 122d may be electrically connected to the 2-3-th connection line 122c through a contact hole of the second insulating layer 115b. Accordingly, a signal from the flexible circuit board (or flexible film) 400 and the printed circuit board 500 may be transmitted to the 2-1-th connection line 122a through the 2-4-th connection line 122d, the 2-3-th connection line 122c, and the 2-2-th connection line 122b.

The 2-5-th connection lines 122e may be disposed on the third insulating layer 115c. The 2-5-th connection line 122e may be disposed in the second non-active area NA2. The 2-5-th connection line 122e may be electrically connected to the 2-4-th connection line 122d through a contact hole of the third insulating layer 115c. Accordingly, a signal from the flexible circuit board (or flexible film) 400 and the printed circuit board 500 may be transmitted to the 2-1-th connection line 122a through the 2-5-th connection line 122e, the 2-4-th connection line 122d, the 2-3-th connection line 122c, and the 2-2-th connection line 122b.

The plurality of first connection lines 121 and the plurality of second connection lines 122 may be formed of any one of a conductive material having excellent ductility or various conductive materials used for the active area AA. For example, the second connection line 122 which is partially disposed in the bending area BA may be configured by a conductive material having excellent ductility, such as gold (Au), silver (Ag), or aluminum (Al), but the exemplary embodiments of the present disclosure are not limited thereto. As another example, the plurality of first connection lines 121 and the plurality of second connection lines 122 may be configured by molybdenum (Mo), chrome (Cr), titanium (Ti), nickel (Ni), neodymium (Nd), copper (Cu), and an alloy of silver (Ag) and magnesium (Mg) or an alloy thereof, but the exemplary embodiments of the present disclosure are not limited thereto.

The fourth insulating layer 115d may be disposed on the plurality of signal lines TL, the plurality of first connection lines 121, and the plurality of second connection lines 122. The fourth insulating layer 115d may be disposed in the remaining area excluding the bending area BA, but the exemplary embodiments of the present disclosure are not limited thereto. The fourth insulating layer 115d may be disposed in the active area AA, the first non-active area NA1, and the second non-active area NA2. A part of the fourth insulating layer 115d disposed in the bending area BA may be removed. The fourth insulating layer 115d may be configured by an organic insulating material, but the exemplary embodiments of the present disclosure are not limited thereto. For example, the fourth insulating layer 115d may be configured by a photo resist, polyimide (PI), or photo acrylic material, but the exemplary embodiments of the present disclosure are not limited thereto.

Referring to FIG. 9 together, the fourth insulating layer 115d may cover top surfaces and side surfaces of the plurality of signal lines TL. Further, the top surface of the fourth insulating layer 115d may be in contact with bottom surfaces of the plurality of banks BNK.

The plurality of banks BNK may be disposed on the fourth insulating layer 115d in the active area AA. The plurality of banks BNK may be disposed so as to overlap each of the plurality of sub pixels. One or more micro LEDs (ED) which emit the same color light may be disposed above each of the plurality of banks BNK.

A plurality of contact electrodes CCE may be disposed on the fourth insulating layer 115d in the active area AA. The plurality of contact electrodes CCE may supply a cathode voltage from the pixel driving circuit PD to the second electrode CE2.

The first electrode CE1 may be disposed on the bank BNK. For example, the first electrode CE1 may be disposed to extend toward the top of an adjacent bank BNK from the fourth insulating layer 115d. The first electrode CE1 may be disposed on the top surface of the bank BNK, the side surface of the bank BNK, and the fourth insulating layer 115d. For example, the first electrode CE1 may be electrically connected to the signal line TL through the contact hole CH disposed on the fourth insulating layer 115d and may extend from the fourth insulating layer 115d to the side surface of the bank BNK and the top surface of the bank BNK.

Referring to FIG. 9, the first electrode CE1 may include a first part P1, a second part P2, and a third part P3.

The first part P1 is a part which is electrically connected to the micro LED (ED) and is disposed on the top surface of the plurality of banks BNK and may be formed to have a size corresponding to the micro LED (ED).

The second part P2 extends from the first part P1 to be disposed on the side surfaces of the plurality of banks BNK. The second part P2 may extend in the first direction DR1 on the plurality of banks BNK. Therefore, the second part P2 may be disposed on the side surfaces of the plurality of banks BNK which is opposite in the first direction DR1.

The third part P3 extends from the second part P2 to be disposed on the outside of the plurality of banks BNK. For example, the third part P3 may be disposed on the same layer as the bank BNK. For example, the third part P3 is disposed on the fourth insulating layer 115d and may be in contact with a top surface of the fourth insulating layer 115d.

The third part P3 may include a 3-1-th part P3-1 (which, in some embodiments, may be referred to as a first sub-part) extending from the second part P2 in the first direction DR1 and a 3-2-th part P3-2 (which, in some embodiments, may be referred to as a second sub-part) extending from the 3-1-th part P3-1 in the second direction DR2.

The 3-1-th part P3-1 may not overlap the plurality of signal lines TL. For example, the 3-1-th part P3-1 may be disposed between one pair of signal lines TL. Referring to FIG. 9, the 3-1-th part P3-1 is disposed between the first signal line TL1 and the second signal line TL2.

The 3-2-th part P3-2 may overlap the plurality of signal lines TL. The 3-2-th part P3-2 may be electrically connected to the plurality of signal lines TL through the contact hole CH disposed on the fourth insulating layer 115d. Referring to FIG. 9, the 3-2-th part P3-2 may be connected to the first signal line TL1 through the contact hole CH. Further, the 3-2-th part P3-2 may be connected to the second signal line TL2 through the contact hole CH. That is, the 3-2-th part P3-2 may be a plurality of first electrodes CE1 which is directly connected to the plurality of signal lines TL.

In the meantime, even though the first sub pixel SP1 has been described with reference to FIG. 9, the second sub pixel SP2 and the third sub pixel SP3 may have substantially the same structure as the first sub pixel SP1. That is, in the second sub pixel SP2 and the third sub pixel SP3, the first electrode CE1 may include a first part P1 disposed on the plurality of banks BNK, a second part P2 disposed on a side surface of the plurality of banks BNK, and a third part P3 at the outside of the plurality of banks BNK. Further, in the second sub pixel SP2 and the third sub pixel SP3, the third part P3 of the first electrode CE1 may include a 3-1-th part P3-1 extending from the second part P2 in the first direction DR1 and a 3-2-th part P3-2 extending from the 3-1-th part P3-1 to the second direction DR2. The 3-1-th part P3-1 of the second sub pixel SP2 may be disposed between the third signal line TL3 and the fourth signal line TL4 and the 3-1-th part P3-1 of the third sub pixel may be disposed between the fifth signal line TL5 and the sixth signal line TL6. The 3-2-th part P3-2 of the second sub pixel SP2 may be connected to the third signal line TL3 and the fourth signal line TL4 and the 3-2-th part P3-2 of the third sub pixel SP3 may be connected to the fifth signal line TL5 and the sixth signal line TL6.

In the meantime, each of the first part P1, the second part P2, and the third part P3 of the plurality of the first electrode CE1 may be integrally formed. That is, the plurality of first electrodes CE1 may be formed on the same layer with the same material.

Referring to FIG. 10, the first electrode CE1 may be configured by a plurality of conductive layers. For example, the first electrode CE1 may include a first conductive layer CE1a, a second conductive layer CE1b, a third conductive layer CE1c, and a fourth conductive layer CE1d, but the exemplary embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, the first conductive layer CE1a, the second conductive layer CE1b, the third conductive layer CE1c, and the fourth conductive layer CE1d may be configured by titanium (Ti), molybdenum (Mo), aluminum (Al), or titanium (Ti) and indium tin oxide (ITO), but the exemplary embodiments of the present disclosure are not limited thereto.

According to the present disclosure, some conductive layer having a good reflection efficiency, among a plurality of conductive layers which configures the first electrode CE1 may be configured as an alignment key for alignment of the micro LED (ED) and/or a reflective plate. For example, the second conductive layer CE1b, among the plurality of conductive layers of the first electrode CE1, may include a reflective material. For example, the second conductive layer CE1b may include aluminum (Al), but the exemplary embodiments of the present disclosure are not limited thereto. Therefore, the second conductive layer CE1b may be configured as a reflective plate. Further, the second conductive layer CE1b has a high reflection efficiency to be easily identified during the manufacturing process so that a position of the micro LED (ED) or a transfer position may be aligned based on the second conductive layer CE1b.

For example, in order to configure the second conductive layer CE1b as a reflective plate, the third conductive layer CE1c and the fourth conductive layer CE1d which cover the second conductive layer CE1b may be partially removed or etched. For example, a part of the third conductive layer CE1c and the fourth conductive layer CE1d disposed on the bank BNK is removed or etched to expose a top surface of the second conductive layer CE1b. For example, a center portion and an edge portion (or a boundary portion) of the third conductive layer CE1c and the fourth conductive layer CE1d in which a solder pattern SDP is disposed remain and the remaining portion excluding the portions may be removed. For example, an edge portion (or a boundary portion) of each of the third conductive layer CE1c formed of titanium (Ti) and the fourth conductive layer CE1d formed of indium tin oxide (ITO) may not be etched. Therefore, corrosion of another conductive layer of the first electrode CE1 caused by tetramethylammonium hydroxide (TMAH) solution which is used for the mask process of the first electrode CE1 may be suppressed.

According to the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which is adhesive to the solder pattern SPD, and has anti-corrosion and acid resistance. However, the exemplary embodiments of the present disclosure are not limited thereto.

The first conductive layer CE1a, the second conductive layer CE1b, the third conductive layer CE1c, and the fourth conductive layer CE1d are sequentially deposited, and then are subject to a photolithographic process and an etching process to be patterned, but the exemplary embodiments of the present disclosure are not limited thereto.

According to the present disclosure, the contact electrode CCE and the pad electrode PE disposed on the same layer as the first electrode CE1 may be configured by multiple layers of conductive materials, but the exemplary embodiment of the present disclosure are not limited thereto. For example, the contact electrode CCE and the pad electrode PE may be formed of multiple layers of indium tin oxide (ITO)/titanium (Ti)/aluminum (Al)/titanium (Ti), but the exemplary embodiments of the present disclosure are not limited thereto.

According to the present disclosure, in each of the plurality of sub pixels, a solder pattern SDP may be disposed on the first electrode CE1. The solder pattern SDP bonds the micro LED (ED) to the first electrode CE1 to electrically connect the first electrode CE1 and the micro LED (ED). For example, the first electrode CE1 and the anode electrode 134 of the micro LED (ED) may be electrically connected through eutectic bonding using the solder pattern SDP, but the exemplary embodiments of the present disclosure are not limited thereto. For example, when the solder pattern SDP is configured by indium (In) and the anode electrode 134 of the micro LED (ED) is configured by gold (Au), the solder pattern SDP and the anode electrode 134 may be bonded by applying heat and a pressure during the transfer process of the micro LED (ED). The micro LED (ED) may be bonded to the solder pattern SDP and the first electrode CE1 using the eutectic bonding without a separate adhesive material. For example, the solder pattern SDP may be configured by indium (In), tin (Sn), or an alloy thereof, but the exemplary embodiments of the present disclosure are not limited thereto. For example, the solder pattern SDP may be a bonding pad or an adhesive pad, but the exemplary embodiments of the present disclosure are not limited thereto. According to the present disclosure, the passivation layer 116 may be disposed on the plurality of first electrodes CE1, the plurality of contact electrodes CCE, and the fourth insulating layer 115d. For example, the passivation layer 116 may be disposed in the active area AA, the first non-active area NA1, and the second non-active area NA2. A part of the passivation layer 116 disposed in the bending area BA may be removed. A part of the passivation layer 116 which covers a plurality of pad electrodes PE in the second non-active area NA2 may be removed. The passivation layer 116 is disposed so as to cover the remaining area excluding an area in which the bending area BA, the plurality of pad electrodes PE, and the solder pattern SDP are disposed to reduce permeation of moisture or impurity introduced to the micro LED (ED). For example, the passivation layer 116 may be configured by a single layer or multiple layers of silicon oxide (SiOx) or silicon nitride (SiNx), but the exemplary embodiments of the present disclosure are not limited thereto. For example, the passivation layer 116 may be a protection layer or an insulating layer, but the exemplary embodiments of the present disclosure are not limited thereto. For example, the passivation layer 116 may include a hole which exposes the solder pattern SDP.

In each of the plurality of sub pixels, the micro LED (ED) may be disposed on the solder pattern SDP. In the first sub pixel SP1, a first micro LED 130 may be disposed. In the second sub pixel SP2, a second micro LED 140 may be disposed. In the third sub pixel SP3, a third micro LED 150 may be disposed.

The micro LED (ED) may be formed on a silicon wafer using metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or a sputtering method. However, the exemplary embodiments of the present disclosure are not limited thereto.

Referring to FIG. 10, the first micro LED 130 may include an anode electrode 134, a first semiconductor layer 131, an active layer 132, a second semiconductor layer 133, a cathode electrode 135, and an encapsulation film 136, but the exemplary embodiments of the present disclosure are not limited thereto. For example, the encapsulation film 136 may not be included in the first micro LED 130.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented by a compound semiconductor, such as a III-V group or a II-VI group and may be doped with an impurity (or dopant). For example, one of the first semiconductor layer 131 and the second semiconductor layer 133 may be an n-type impurity doped semiconductor layer and the other one may be a p-type impurity doped semiconductor, but the exemplary embodiments of the present disclosure are not limited thereto. For example, one or more of the first semiconductor layer 131 and the second semiconductor layer 133 may be a layer in which n-type or p-type impurity is doped on a material, such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs). However, the exemplary embodiments of the present disclosure are not limited thereto. For example, the n-type impurity may be silicon (Si), germanium (Ge), selenium (Sc), carbon (C), tellurium (Te), or tin (Sn), but the exemplary embodiments of the present disclosure are not limited thereto. For example, the p-type impurity may be magnesium (Mg), zinc (Zn), calcium (Ca), strontium (Sr), barium (Ba), or beryllium (Be), but the exemplary embodiments of the present disclosure are not limited thereto.

For example, each the first semiconductor layer 131 and the second semiconductor layer 133 may be a nitride semiconductor including an n-type impurity or a nitride semiconductor including a p-type impurity, but the exemplary embodiments of the present disclosure are not limited thereto. For example, the first semiconductor layer 131 may be a nitride semiconductor including a p-type impurity and the second semiconductor layer 133 may be a nitride semiconductor including an n-type impurity, but the exemplary embodiments of the present disclosure are not limited thereto.

The active layer 132 may be disposed between the first semiconductor layer 131 and the second semiconductor layer 133. The active layer 132 is supplied with holes and electrons from the first semiconductor layer 131 and the second semiconductor layer 133 to emit light. For example, the active layer 132 may be configured of one of a single well structure, a multi-well structure, a signal quantum well structure, a multi-quantum well (MQW) structure, a quantum dot structure, and a quantum line structure, but the exemplary embodiments of the present disclosure are not limited thereto. For example, the active layer 132 may be configured by indium gallium nitride (InGaN) or gallium nitride (GaN), but the exemplary embodiments of the present disclosure are not limited thereto.

As another example, the active layer 132 may have a multi quantum well (MQW) structure having a well layer and a barrier layer with a band gap higher than the well layer. For example, in the active layer 132, InGaN may be configured as a well layer and an AlGaN layer may be configured as a barrier layer, but the exemplary embodiments of the present disclosure are not limited thereto.

The anode electrode 134 may be disposed between the first semiconductor layer 131 and the solder pattern SDP. For example, the anode electrode 134 may electrically connect the first semiconductor layer 131 and the first electrode CE1. The anode voltage output from the pixel driving circuit PD may be applied to the first semiconductor layer 131 through the signal line TL, the first electrode CE1, and the anode electrode 134. For example, the anode electrode 134 may be configured by a conductive material which may form eutectic bonding with the solder pattern SDP, but the exemplary embodiments of the present disclosure are not limited thereto. For example, the anode electrode 134 may be configured by gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the exemplary embodiments of the present disclosure are not limited thereto.

The cathode electrode 135 may be disposed on the second semiconductor layer 133. For example, the cathode electrode 135 may electrically connect the second semiconductor layer 133 and the second electrode CE2. A cathode voltage output from the pixel driving circuit PD may be applied to the second semiconductor layer 133 through the contact electrode CCE, the second electrode CE2, and the cathode electrode 135. The cathode electrode 135 may be configured by a transparent conductive material to allow light emitted from the micro LED (ED) to be directed to the top of the micro LED (ED), but the exemplary embodiments of the present disclosure are not limited thereto. For example, the cathode electrode 135 may be configured by a material, such as indium tin oxide (ITO), indium zinc oxide (IZO), indium gallium zinc oxide (IGZO), but the exemplary embodiments of the present disclosure are not limited thereto.

The encapsulation film 136 may be disposed on at least a part of the first semiconductor layer 131, the active layer 132, the second semiconductor layer 133, the anode electrode 134, and the cathode electrode 135. For example, the encapsulation film 136 may enclose at least a part of the first semiconductor layer 131, the active layer 132, the second semiconductor layer 133, the anode electrode 134, and the cathode electrode 135.

For example, the encapsulation film 136 is formed of an insulating material to protect the first semiconductor layer 131, the active layer 132, and the second semiconductor layer 133. For example, the encapsulation film 136 may be disposed on a side surface of the first semiconductor layer 131, a side surface of the active layer 132, and a side surface of the second semiconductor layer 133.

For example, the encapsulation film 136 may be disposed on at least a part of the anode electrode 134 and the cathode electrode 135, for example, on an edge portion (or a boundary portion or one side) of the anode electrode 134 and an edge portion (or a boundary portion or one side) of the cathode electrode 135. At least a part of the anode electrode 134 is exposed from the encapsulation film 136 so that the anode electrode 134 and the solder pattern SDP may be connected. For example, at least a part of the cathode electrode 135 is exposed from the encapsulation film 136 so that the cathode electrode 135 and the second electrode CE2 may be connected. For example, the encapsulation film 136 may be formed of an insulating material, such as silicon nitride (SiNx) or silicon oxide (SiOx), but the exemplary embodiments of the present disclosure are not limited thereto.

As another example, the encapsulation film 136 has a structure in which a reflective material is dispersed in a resin layer, but the exemplary embodiments of the present disclosure are not limited thereto. For example, the encapsulation film 136 may be manufactured with reflectors with various structures, but the exemplary embodiments of the present disclosure are not limited thereto. Light emitted from the active layer 132 is upwardly reflected by the encapsulation film 136 so that light extraction efficiency may be improved. For example, the encapsulation film 136 may be a reflective layer, but the exemplary embodiments of the present disclosure are not limited thereto.

According to the present disclosure, it is described that the micro LED (ED) has a vertical structure, but the exemplary embodiments of the present disclosure are not limited thereto. For example, the micro LED (ED) may have a lateral structure or a flip-chip structure.

The first micro LED 130 has been described with reference to FIG. 10 and the second micro LED 140 and the third micro LED 150 may have the substantially same structure as the first micro LED 130. For example, the second micro LED 140 and the third micro LED 150 may be substantially the same as the first semiconductor layer 131, the active layer 132, the second semiconductor layer 133, the anode electrode 134, the cathode electrode 135, and the encapsulation film 136 of the first micro LED 130.

According to the present disclosure, in the active area AA, a first optical layer 117a which encloses the plurality of micro LEDs (ED) may be disposed. For example, the first optical layer 117a may be disposed so as to cover the plurality of micro LEDs (ED) and the bank BNK in the area of the plurality of sub pixels. For example, the first optical layer 117a may cover a part of the bank BNK, the passivation layer 116 and between the plurality of micro LEDs (ED). The first optical layer 117a may be disposed or cover between the plurality of micro LEDs (ED) and between the plurality of banks BNK included in one pixel PX. For example, the first optical layer 117a extends in the first direction DR1 and may be spaced apart from each other in the second direction DR2. For example, the first optical layer 117a may be disposed so as to enclose side portions of the micro LED (ED) and the bank BNK between the passivation layer 116 and the second electrode CE2, but the exemplary embodiments of the present disclosure are not limited thereto. For example, the first optical layer 117a may be a diffusion layer or a side wall diffusion layer, but the exemplary embodiments of the present disclosure are not limited thereto.

The first optical layer 117a may include an organic insulating material in which micro particles are dispersed, but the exemplary embodiments of the present disclosure are not limited thereto. For example, the first optical layer 117a may be configured by siloxane in which micro metal particles, such as titanium dioxide (TiO2) particles, are dispersed, but the exemplary embodiments of the present disclosure are not limited thereto. Light from the plurality of micro LEDs (ED) is scattered by micro particles dispersed in the first optical layer 117a to be emitted to the outside of the display apparatus 1000. Accordingly, the first optical layer 117a may improve extraction efficiency of light emitted from the plurality of micro LEDs (ED).

For example, the first optical layer 117a may be disposed in each of the plurality of pixels PX or disposed in some pixel PX disposed in the same row together, but the exemplary embodiments of the present disclosure are not limited thereto. For example, the first optical layer 117a is disposed in each of the plurality of pixels PX or the plurality of pixels PX may share one first optical layer 117a. As another example, each of the plurality of sub pixels separately may include the first optical layer 117a, but the exemplary embodiments of the present disclosure are not limited thereto.

According to the present disclosure, in the active area AA, a second optical layer 117b may be disposed on the passivation layer 116. For example, the second optical layer 117b may be disposed so as to enclose the first optical layer 117a. For example, the second optical layer 117b may be in contact with a side surface of the first optical layer 117a. For example, the second optical layer 117b may be disposed in an area between the plurality of pixels PX. However, the exemplary embodiments of the present disclosure are not limited thereto. For example, the second optical layer 117b may be a diffusion layer, a diffusion layer window, or a window diffusion layer, but the exemplary embodiments of the present disclosure are not limited thereto.

The second optical layer 117b may be configured by an organic insulating material, but the exemplary embodiments of the present disclosure are not limited thereto. The second optical layer 117b may be configured by the same material as the first optical layer 117a, but the exemplary embodiments of the present disclosure are not limited thereto. For example, the first optical layer 117a may include micro particles, but the second optical layer 117b may not include micro particles. For example, the second optical layer 117b may be configured by siloxane, but the exemplary embodiments of the present disclosure are not limited thereto.

For example, a thickness of the first optical layer 117a may be smaller than a thickness of the second optical layer 117b, but the exemplary embodiments of the present disclosure are not limited thereto. Accordingly, in the plan view, an area in which the first optical layer 117a is disposed may include a concave portion which is inwardly dented from an upper surface of the second optical layer 117b.

According to the present disclosure, the second electrode CE2 may be disposed on the first optical layer 117a and the second optical layer 117b. For example, the second electrode CE2 may be electrically connected to the plurality of contact electrodes CCE through a contact hole of the second optical layer 117b. For example, the second electrode CE2 may be disposed on the plurality of micro LEDs (ED). For example, the second electrode CE2 includes a transparent conductive oxide, such as indium tin oxide (ITO) or indium zinc oxide (IZO), but the exemplary embodiments of the present disclosure are not limited thereto. For example, the second electrode CE2 may be disposed to be in contact with the cathode electrode 135. For example, the second electrode CE2 may overlap the first optical layer 117a. For example, the second electrode CE2 may cover a plane at the outside of the first optical layer 117a.

The second electrode CE2 continuously may extend in the second direction DR2 of the substrate 110. Accordingly, the second electrode may be commonly connected to the plurality of pixels PX disposed in the second direction DR2 of the substrate 110. For example, the second electrode CE2 may be commonly connected to the plurality of pixels PX.

According to the present disclosure, the second electrode CE2 may be continuously extended on the first optical layer 117a, the second optical layer 117b, and the micro LED (ED). The area in which the first optical layer 117a is disposed may include a concave portion which is inwardly dented from an upper surface of the second optical layer 117b. Accordingly, the first part of the second electrode CE2 disposed on the first optical layer 117a is disposed along the concave portion so that the first part may be disposed to be lower than the second part of the second electrode CE2 disposed on the second optical layer 117b.

The third optical layer 117c may be disposed on the second electrode CE2. The third optical layer 117c may be disposed so as to overlap the plurality of micro LEDs (ED) and the first optical layer 117a. The third optical layer 117c is disposed above the second electrode CE2 and the plurality of micro LEDs (ED) so that a spot (mura) which may be generated in a part of the plurality of micro LEDs (ED) may be improved. For example, when the plurality of micro LEDs (ED) is transferred onto the substrate 110 of the display apparatus 1000, an area in which the interval between the plurality of micro LEDs (ED) is not uniform may be caused due to a process deviation. When the interval between the plurality of micro LEDs (ED) is not uniform, an emission area of each of the plurality of micro LEDs (ED) may be not uniformly disposed so that a spot (mura) may be visible to a user. Accordingly, the third optical layer 117c which is configured to uniformly diffuse light is configured above the plurality of micro LEDs (ED) so that light emitted from some micro LED (ED) which is visible as mura may be reduced. Accordingly, light emitted from the plurality of micro LEDs (ED) is uniformly diffused by the third optical layer 117c to be extracted to the outside of the display apparatus 1000 so that the luminance uniformity of the display apparatus 1000 may be improved.

The third optical layer 117c may be configured by an organic insulating material in which micro particles are dispersed, but the exemplary embodiments of the present disclosure are not limited thereto. For example, the third optical layer 117c may be configured by siloxane in which micro metal particles, such as titanium dioxide (TiO₂) particles, are dispersed, but the exemplary embodiments of the present disclosure are not limited thereto. For example, the third optical layer 117c may be configured by the same material as the first optical layer 117a, but the exemplary embodiments of the present disclosure are not limited thereto. For example, the third optical layer 117c may be a diffusion layer or a upward diffusion layer, but the exemplary embodiments of the present disclosure are not limited thereto.

According to the present disclosure, light from the plurality of micro LEDs (ED) is scattered by micro particles dispersed in the third optical layer 117c to be emitted to the outside of the display apparatus 1000. The third optical layer 117c uniformly mixes light emitted from the plurality of micro LEDs (ED) to further improve the luminance uniformity of the display apparatus 1000. The light extraction efficiency of the display apparatus 1000 may be improved by light scattered from the plurality of micro particles so that the display apparatus 1000 may be driven at a low power.

In the active area AA, a black matrix BM may be disposed on the second electrode CE2, the first optical layer 117a, the second optical layer 117b, and the third optical layer 117c. For example, the contact hole of the second optical layer 117b may be filled with the black matrix BM. The black matrix BM is configured to cover the active area AA to reduce color mixture and external light reflection of light of the plurality of sub pixels. For example, the black matrix BM is disposed in the contact hole through which the second electrode CE2 and the contact electrode CCE are connected so that light leakage between the plurality of adjacent sub pixels may be suppressed.

For example, the black matrix BM may be configured by an opaque material, but the exemplary embodiments of the present disclosure are not limited thereto. For example, the black matrix BM may be configured by an organic insulating material to which black pigment or black dye is added, but the exemplary embodiments of the present disclosure are not limited thereto.

In the active area AA, a cover layer 118 may be disposed on the black matrix BM. The cover layer 118 may protect configurations below the cover layer 118. For example, the cover layer 118 may be configured by an organic insulating material, but the exemplary embodiments of the present disclosure are not limited thereto. For example, the cover layer 118 may be configured by a photo resist, polyimide (PI), or photo acrylic material, but the exemplary embodiments of the present disclosure are not limited thereto. For example, the cover layer 118 may be an over coating layer or an insulating layer, but the exemplary embodiments of the present disclosure are not limited thereto.

A polarization layer 293 may be disposed on the cover layer 118 by means of the first adhesive layer 291. A cover member 200 may be disposed on the polarization layer 293 by means of the second adhesive layer 295. For example, the first adhesive layer 291 and the second adhesive layer 295 may include an optically clear adhesive (OCA), an optically clear resin (OCR), or a pressure sensitive adhesive (PSA), but the exemplary embodiments of the present disclosure are not limited thereto.

According to the present disclosure, a plurality of pad electrodes PE may be disposed on the fourth insulating layer 115d in the second non-active area NA2. The plurality of pad electrodes PE is disposed on the plurality of signal lines TL and may be disposed on the same layer as the plurality of first electrodes CE1.

At least a part of the plurality of pad electrodes PE may be exposed from the passivation layer 116. For example, the plurality of pad electrodes PE may be electrically connected to the 2-5-th connection line 122e through a contact hole of the fourth insulating layer 115d.

The adhesive layer ACF may be disposed on the plurality of pad electrodes PE. The adhesive layer ACF may be an adhesive layer in which conductive balls are dispersed in an insulating material, but the exemplary embodiments of the present disclosure are not limited thereto. When heat or a pressure is applied to the adhesive layer ACF, the conductive balls are electrically connected in a portion applied with the heat or pressure to have a conductive property. The adhesive layer ACF is disposed between the plurality of pad electrodes PE and the flexible circuit board (or flexible film) 400, the flexible circuit board (or flexible film) 400 may be attached or bonded to the plurality of pad electrodes PE. For example, the adhesive layer ACF may be anisotropic conductive film, but the exemplary embodiments of the present disclosure are not limited thereto.

The flexible circuit board (or flexible film) 400 may be disposed on the adhesive layer ACF. The flexible circuit board (or flexible film) 400 may be electrically connected to the plurality of pad electrodes PE through the adhesive layer ACF. Accordingly, a signal output from the flexible circuit board (or flexible film) 400 and the printed circuit board 500 may be transmitted to the pixel driving circuit PD of the active area AA through the plurality of pad electrodes PE, the 2-4-th connection line 122d, the 2-3-th connection line 122c, the 2-2-th connection line 122b, and the 2-1-th connection line 122a.

The plurality of signal lines may electrically transmit an anode voltage from the pixel driving circuit to the first electrode of the plurality of sub pixels. Specifically, the plurality of signal lines is disposed between adjacent sub pixels and may be electrically connected to the first electrode extending from the bank. Accordingly, the plurality of signal lines is disposed on the same layer as the first electrode to be integrally implemented. However, when the plurality of signal lines and the first electrode are disposed on the same layer, a line width of the plurality of signal lines and an interval between the plurality of signal lines are limited by an interval of the plurality of banks. For example, when one pair of first electrodes is disposed on one bank, one pair of first electrodes may extend to different directions on one bank. For example, one pair of signal lines connected to one pair of first electrodes may be disposed on both sides of the bank. Therefore, two signal lines may be disposed between adjacent banks. Accordingly, if the interval between the banks is narrow, it is difficult to ensure the interval between the plurality of signal lines and there may be a possibility of short-circuit of adjacent signal lines which transmit different signals. However, in order to suppress the short-circuit problem, if the line width of the plurality of signal lines is reduced, a resistance of the signal lines is increased to increase power consumption or cause voltage drop. Further, in order to improve the problem generated in the signal line, an interval between the banks is increased, a degree of integration of pixels is lowered so that it is difficult to implement a display apparatus with a high resolution.

In the display apparatus 1000 according to the exemplary embodiment of the present disclosure, the plurality of signal lines TL and the plurality of first electrodes CE1 are disposed on different layers. For example, the first electrode CE1 may be disposed above the plurality of signal lines TL. Specifically, the plurality of signal lines TL may be disposed below the plurality of banks and the first electrode CE1 may be disposed above the plurality of banks BNK. Further, the plurality of signal lines TL and the first electrode CE1 may be electrically connected through the contact hole CH disposed on the fourth insulating layer 115d. Accordingly, the plurality of signal lines TL may be disposed regardless of the interval of the plurality of banks BNK. For example, the plurality of signal lines TL may be disposed so as to overlap the plurality of banks BNK below the plurality of banks BNK.

Accordingly, in the display apparatus 1000 according to the exemplary embodiment of the present disclosure, the interval between the plurality of signal lines TL may expand and the problem in that the plurality of signal lines TL which transmits different signals and are disposed to be adjacent to each other is electrically connected may be suppressed. Accordingly, the problem of the short-circuit of the plurality of signal lines TL may be suppressed and the liftspan of the display apparatus 1000 may be improved.

Further, in the display apparatus 1000 according to the exemplary embodiment of the present disclosure, the line width of the plurality of signal lines TL may expand and the resistance problem of the plurality of signal lines TL may be improved. Accordingly, a voltage drop problem or an increased power consumption problem which may occur according to the plurality of signal lines TL may be suppressed. Therefore, the display apparatus 1000 according to the exemplary embodiment of the present disclosure may be driven at a low power and the lifespan of the display apparatus 1000 may be improved.

Further, in the display apparatus 1000 according to the exemplary embodiment of the present disclosure, the plurality of banks BNK may be disposed regardless of the line width of the plurality of signal lines TL. Accordingly, the interval between the plurality of banks BNK may be reduced. As a result, the plurality of pixels PX disposed on the plurality of banks BNK may be integrated and a display apparatus with a high resolution may be implemented.

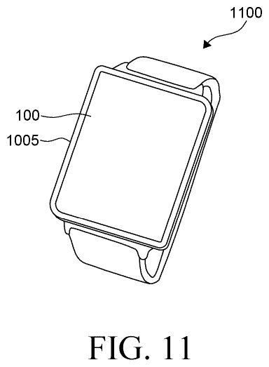

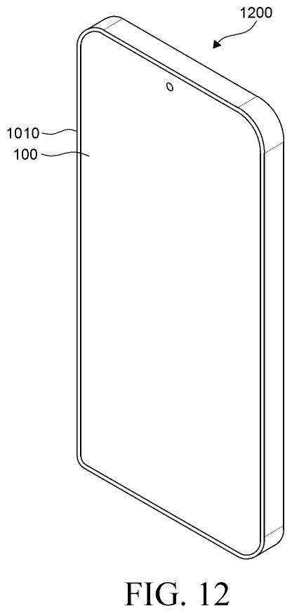

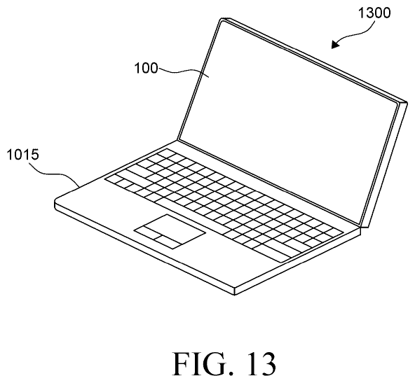

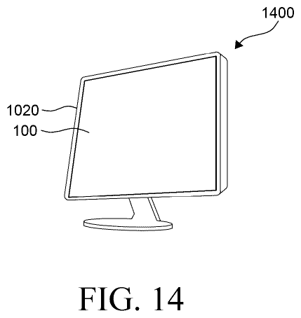

FIGS. 11 to 14 are views illustrating devices to which a display apparatus according to exemplary embodiments of the present disclosure is applied.

Referring to FIGS. 11 to 14, the display apparatus 1000 according to the exemplary embodiments of the present disclosure may be included in various devices or electronic devices. For example, referring to FIGS. 11 to 14, various electronic devices may include a wearable device 1100, a mobile device 1200, a laptop 1300, and a monitor or TV 1400, but the exemplary embodiments of the present disclosure are not limited thereto.

Each of the wearable device 1100, the mobile device 1200, the laptop 1300, and a monitor or TV 1400 may include case units 1005, 1010, 1015, and 1020 and display panel 100 and the display apparatus 1000 according to the exemplary embodiments of the present disclosure which have been described in FIGS. 1 to 10, respectively.

For example, the display apparatus 1000 according to the exemplary embodiment of the present disclosure may be applicable to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic note, an electronic book, a portable multimedia player (PMP), a personal digital assistant (PDA), an MP3 player, a mobile medical apparatus, a desktop PC, a laptop PC, a netbook computer, a workstation, a navigation, a display apparatus for a vehicle, a theatrical display apparatus, a television, a wallpaper device, a signage device, a game device, a laptop, a monitor, a camera, a camcorder, and a consumer electronics device.

The exemplary embodiments of the present disclosure can also be described as follows:

According to an aspect of the present disclosure, there is provided a display apparatus. The display apparatus comprises a substrate, one or more pixel driving circuits disposed on the substrate, a plurality of insulating layer disposed on the pixel driving circuit, a plurality of banks disposed on the plurality of insulating layers, a plurality of micro LEDs which is disposed on the plurality of banks and is electrically connected to the pixel driving circuit, a plurality of first electrodes which is disposed between the plurality of banks and the plurality of micro LEDs and a plurality of signal lines which is in direct contact with the plurality of first electrodes and is disposed below the plurality of banks so as to overlap the plurality of banks.

The plurality of first electrodes may be disposed on top surfaces and side surfaces of the plurality of banks.

Each of the plurality of banks may extend in a first direction and each of the plurality of first electrodes may include a first part disposed on the top surfaces of the plurality of banks and a second part which extends from the first part on the plurality of banks in the first direction to be disposed on the side surfaces of the plurality of banks which are opposite in the first direction.

Each of the plurality of first electrodes may further include a third part which extends from the second part to be in contact with top surfaces of the plurality of insulating layers.

The third part may overlap the plurality of signal lines and be electrically connected to the plurality of signal lines through a contact hole disposed in the plurality of insulating layers.

The third part may include a first sub-part extending from the second part in the first direction and a second sub-part extending from the first sub-part in a second direction.

The first part, the second part, and the third part may be integrally formed.

The plurality of signal lines may extend in the first direction and be electrically connected to a plurality of micro LEDs disposed in the first direction, among the plurality of micro LEDs.

One bank of the plurality of banks may overlap one pair of signal lines, among the plurality of signal lines.

One pair of micro LEDs which emit the same color light, among the plurality of micro LEDs, may be disposed on one bank.

The display apparatus may further comprise a flexible circuit board and a plurality of pad electrodes which is electrically connected to the flexible circuit board, the plurality of pad electrodes may be disposed on the plurality of signal lines and be disposed on the same layer as the plurality of first electrodes.

The plurality of insulating layers may include an organic insulating layer which is in contact with bottom surfaces of the plurality of banks, and the organic insulating layer may cover top surfaces and side surfaces of the plurality of signal lines.

The plurality of pad electrodes and the plurality of first electrodes may be disposed on the organic insulating layer.

Each of the plurality of micro LEDs may include an anode electrode, a first semiconductor layer disposed on the anode electrode, an active layer disposed on the first semiconductor layer, a second semiconductor layer disposed on the active layer and a cathode electrode disposed on the second semiconductor layer.

The display apparatus may further comprise a solder pattern which is disposed between the first electrode and the anode electrode, wherein the first electrode and the anode electrode are electrically connected by eutectic bonding using the solder pattern and the first electrode electrically connects the pixel driving circuit and the anode electrode of the micro LED.

According to another aspect of the present disclosure, there is provided a display apparatus. The display apparatus comprises a substrate including an active area including a plurality of sub pixels and a non-active area, one or more pixel driving circuits disposed on the substrate, a plurality of insulating layers disposed on the substrate, a plurality of banks disposed in the plurality of sub pixels on the plurality of insulating layers, a plurality of micro LEDs disposed on the plurality of banks, a plurality of first electrodes which is disposed between the plurality of banks and the plurality of micro LEDs and a plurality of signal lines which electrically connects the plurality of first electrodes and the pixel driving circuit, wherein the plurality of signal lines overlaps the plurality of banks and the plurality of signal lines is conductive layers which are disposed to be adjacent to the bank, among conductive layers disposed below the bank.

The plurality of signal lines may be disposed in an area excluding an area between banks which are adjacent in a second direction, among the plurality of banks.

Each of the plurality of banks may have a long axis in a first direction and the plurality of signal lines extends in the first direction.

One pair of micro LEDs, among the plurality of micro LEDs, may be disposed on each of the plurality of banks and the pair of micro LEDs may be disposed along the first direction.

One pair of signal lines, among the plurality of signal lines, may overlap a same bank, among the plurality of banks and an interval between the pair of signal lines may be smaller than a length of a short axis of the plurality of banks.

The pair of signal lines may be electrically connected to a plurality of micro LEDs which emits the same color light, among the plurality of micro LEDs.

Each of the plurality of micro LEDs may include an anode electrode, a first semiconductor layer disposed on the anode electrode, an active layer disposed on the first semiconductor layer, a second semiconductor layer disposed on the active layer, and a cathode electrode disposed on the second semiconductor layer and have a vertical type structure.

The display apparatus may further comprise a solder pattern which is disposed between the first electrode and the anode electrode, wherein the anode electrode is bonded to the first electrode by eutectic bonding using the solder pattern.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate;
one or more pixel driving circuits on the substrate;
a plurality of insulating layers on the pixel driving circuit;
a plurality of banks on the plurality of insulating layers;
a plurality of micro LEDs on the plurality of banks and electrically connected to the pixel driving circuit;
a plurality of first electrodes which are interposed between the plurality of banks and the plurality of micro LEDs; and
a plurality of signal lines which is in direct contact with the plurality of first electrodes and is disposed below the plurality of banks so as to overlap the plurality of banks.

2. The display apparatus according to claim 1, wherein each of the plurality of banks extends in a first direction, and
each of the plurality of first electrodes includes:
a first part on top surfaces of the plurality of banks; and
a second part which extends from the first part on the plurality of banks in the first direction to be disposed on side surfaces of the plurality of banks which are opposite in the first direction.

3. The display apparatus according to claim 2, wherein each of the plurality of first electrodes further includes a third part which extends from the second part to be in contact with top surfaces of the plurality of insulating layers.

4. The display apparatus according to claim 3, wherein the third part overlaps the plurality of signal lines and is electrically connected to the plurality of signal lines through a contact hole disposed in the plurality of insulating layers.

5. The display apparatus according to claim 3, wherein the third part includes:
a first sub-part extending from the second part in the first direction; and
a second sub-part extending from the first sub-part in a second direction different from the first direction.

6. The display apparatus according to claim 2, wherein the plurality of signal lines extends in the first direction and is electrically connected to a plurality of micro LEDs disposed in the first direction, among the plurality of micro LEDs.

7. The display apparatus according to claim 1, wherein one bank of the plurality of banks overlaps one pair of signal lines, among the plurality of signal lines.

8. The display apparatus according to claim 7, wherein one pair of micro LEDs which emit the same color light, among the plurality of micro LEDs, is on one bank.

9. The display apparatus according to claim 1, further comprising:
a flexible circuit board; and
a plurality of pad electrodes which is electrically connected to the flexible circuit board,
wherein the plurality of pad electrodes is on the plurality of signal lines and is on the same layer as the plurality of first electrodes.

10. The display apparatus according to claim 9, wherein the plurality of insulating layers includes an organic insulating layer which is in contact with bottom surfaces of the plurality of banks, and the organic insulating layer covers top surfaces and side surfaces of the plurality of signal lines.

11. The display apparatus according to claim 10, wherein the plurality of pad electrodes and the plurality of first electrodes are disposed on the organic insulating layer.

12. The display apparatus according to claim 1, wherein each of the plurality of micro LEDs includes:
an anode electrode;
a first semiconductor layer on the anode electrode;
an active layer on the first semiconductor layer;
a second semiconductor layer on the active layer; and
a cathode electrode on the second semiconductor layer.

13. The display apparatus according to claim 12, further comprising:
a solder pattern between the first electrode and the anode electrode,
wherein the first electrode and the anode electrode are electrically connected by eutectic bonding using the solder pattern, and
wherein the first electrode electrically connects the pixel driving circuit and the anode electrode of the micro LED.

14. A display apparatus comprising:
a substrate including a non-active area and an active area including a plurality of sub pixels;
one or more pixel driving circuits on the substrate;
a plurality of insulating layers on the substrate;
a plurality of banks disposed in the plurality of sub pixels on the plurality of insulating layers;
a plurality of micro LEDs on the plurality of banks;
a plurality of first electrodes which are interposed between the plurality of banks and the plurality of micro LEDs; and
a plurality of signal lines which electrically connects the plurality of first electrodes and the pixel driving circuit,
wherein the plurality of signal lines overlaps the plurality of banks, and
wherein the plurality of signal lines are conductive layers which are disposed to be adjacent to the bank, among conductive layers disposed below the bank.

15. The display apparatus according to claim 14, wherein the plurality of signal lines is disposed in an area excluding an area between banks which are adjacent in a second direction, among the plurality of banks and wherein each of the plurality of banks has a short axis in the second direction.

16. The display apparatus according to claim 14, wherein each of the plurality of banks has a long axis in a first direction and the plurality of signal lines extends in the first direction, and
wherein one pair of micro LEDs, among the plurality of micro LEDs, is disposed on each of the plurality of banks and the pair of micro LEDs is disposed along the first direction.

17. The display apparatus according to claim 14, wherein one pair of signal lines, among the plurality of signal lines, overlaps a same bank, among the plurality of banks and an interval between the pair of signal lines is smaller than a length of a short axis of the plurality of banks.

18. The display apparatus according to claim 17, wherein the pair of signal lines is electrically connected to a plurality of micro LEDs which emits the same color light, among the plurality of micro LEDs.

19. The display apparatus according to claim 14, wherein each of the plurality of micro LEDs includes an anode electrode, a first semiconductor layer on the anode electrode, an active layer on the first semiconductor layer, a second semiconductor layer on the active layer, and a cathode electrode on the second semiconductor layer and has a vertical type structure.

20. The display apparatus according to claim 19, further comprising:
a solder pattern between the first electrode and the anode electrode,
wherein the anode electrode is bonded to the first electrode by eutectic bonding using the solder pattern.
